(19) United States
(12) Patent Application Publication
(10) Pub. No.: US 2026/0353610 A1
(43) Pub. Date: Nov. 5, 2026

(54) Passive Inter-Surface Cavity Device with High-Curvature Geometric Features

(71) Applicant: AtomBeam Technologies Inc., Moraga, CA (US)

(72) Inventor: Brian Galvin, Silverdale, WA (US)

(21) Appl. No.: 19/649,461

(22) Filed: Apr. 16, 2026

Related U.S. Application Data
(63) Continuation-in-part of application No. 19/458,428, filed on Jan. 23, 2026.
(60) Provisional application No. 63/003,147, filed on Mar. 31, 2020.
(60) Provisional application No. 63/003,151, filed on Mar. 31, 2020.
(60) Provisional application No. 63/869,452, filed on Aug. 24, 2025.
(60) Provisional application No. 63/869,434, filed on Aug. 24, 2025.
(60) Provisional application No. 63/870,101, filed on Aug. 25, 2025.
(60) Provisional application No. 63/870,103, filed on Aug. 25, 2025.
(60) Provisional application No. 63/870,096, filed on Aug. 25, 2025.
(60) Provisional application No. 63/870,098, filed on Aug. 25, 2025.
(60) Provisional application No. 63/874,637, filed on Sep. 3, 2025.
(60) Provisional application No. 63/874,639, filed on Sep. 3, 2025.
(60) Provisional application No. 63/874,640, filed on Sep. 3, 2025.
(60) Provisional application No. 63/874,641, filed on Sep. 3, 2025.
(60) Provisional application No. 63/901,636, filed on Oct. 18, 2025.
(60) Provisional application No. 63/901,638, filed on Oct. 18, 2025.
(60) Provisional application No. 63/901,640, filed on Oct. 18, 2025.
(60) Provisional application No. 63/901,646, filed on Oct. 18, 2025.
(60) Provisional application No. 63/901,649, filed on Oct. 18, 2025.
(60) Provisional application No. 63/901,823, filed on Oct. 19, 2025.
(60) Provisional application No. 63/901,826, filed on Oct. 19, 2025.
(60) Provisional application No. 63/901,834, filed on Oct. 19, 2025.
(60) Provisional application No. 63/901,866, filed on Oct. 20, 2025.
(60) Provisional application No. 63/902,501, filed on Oct. 20, 2025.
(60) Provisional application No. 63/915,125, filed on Nov. 10, 2025.
(60) Provisional application No. 63/915,133, filed on Nov. 10, 2025.
(60) Provisional application No. 63/915,138, filed on Nov. 10, 2025.
(60) Provisional application No. 63/916,439, filed on Nov. 12, 2025.
(60) Provisional application No. 63/916,455, filed on Nov. 13, 2025.
(60) Provisional application No. 63/916,458, filed on Nov. 13, 2025.
(60) Provisional application No. 63/916,468, filed on Nov. 13, 2025.
(60) Provisional application No. 63/916,471, filed on Nov. 13, 2025.
(60) Provisional application No. 63/916,473, filed on Nov. 13, 2025.
(60) Provisional application No. 63/916,983, filed on Nov. 13, 2025.
(60) Provisional application No. 63/919,475, filed on Nov. 17, 2025.
(60) Provisional application No. 63/919,479, filed on Nov. 17, 2025.
(60) Provisional application No. 63/921,275, filed on Nov. 20, 2025.
(60) Provisional application No. 63/921,271, filed on Nov. 20, 2025.
(60) Provisional application No. 63/921,288, filed on Nov. 20, 2025.
(60) Provisional application No. 63/921,276, filed on Nov. 20, 2025.
(60) Provisional application No. 63/921,280, filed on Nov. 20, 2025.
(60) Provisional application No. 63/923,014, filed on Nov. 21, 2025.
(60) Provisional application No. 63/923,021, filed on Nov. 22, 2025.
(60) Provisional application No. 63/924,560, filed on Nov. 24, 2025.
(60) Provisional application No. 63/924,554, filed on Nov. 24, 2025.
(60) Provisional application No. 63/924,573, filed on Nov. 25, 2025.
(60) Provisional application No. 63/924,600, filed on Nov. 25, 2025.
(60) Provisional application No. 63/924,566, filed on Nov. 25, 2025.
(60) Provisional application No. 63/926,434, filed on Nov. 26, 2025.
(60) Provisional application No. 63/926,417, filed on Nov. 26, 2025.
(60) Provisional application No. 63/926,413, filed on Nov. 26, 2025.
(60) Provisional application No. 63/926,411, filed on Nov. 26, 2025.
(60) Provisional application No. 63/926,390, filed on Nov. 26, 2025.
(60) Provisional application No. 63/926,392, filed on Nov. 26, 2025.
(60) Provisional application No. 63/926,397, filed on Nov. 26, 2025.
(60) Provisional application No. 63/926,405, filed on Nov. 26, 2025.
(60) Provisional application No. 63/926,421, filed on Nov. 26, 2025.
(60) Provisional application No. 63/926,425, filed on Nov. 26, 2025.
(60) Provisional application No. 63/926,430, filed on Nov. 26, 2025.
(60) Provisional application No. 63/927,212, filed on Nov. 28, 2025.
(60) Provisional application No. 63/927,196, filed on Nov. 28, 2025.
(60) Provisional application No. 63/927,181, filed on Nov. 28, 2025.
(60) Provisional application No. 63/927,187, filed on Nov. 28, 2025.
(60) Provisional application No. 63/927,189, filed on Nov. 28, 2025.
(60) Provisional application No. 63/927,202, filed on Nov. 28, 2025.
(60) Provisional application No. 63/927,208, filed on Nov. 28, 2025.
(60) Provisional application No. 63/928,801, filed on Dec. 1, 2025.
(60) Provisional application No. 63/928,805, filed on Dec. 1, 2025.
(60) Provisional application No. 63/928,808, filed on Dec. 1, 2025.
(60) Provisional application No. 63/928,813, filed on Dec. 1, 2025.
(60) Provisional application No. 63/928,819, filed on Dec. 1, 2025.
(60) Provisional application No. 63/928,823, filed on Dec. 1, 2025.
(60) Provisional application No. 63/930,614, filed on Dec. 3, 2025.
(60) Provisional application No. 63/931,463, filed on Dec. 4, 2025.
(60) Provisional application No. 63/933,237, filed on Dec. 7, 2025.
(60) Provisional application No. 63/933,225, filed on Dec. 7, 2025.
(60) Provisional application No. 63/933,240, filed on Dec. 7, 2025.
(60) Provisional application No. 63/933,227, filed on Dec. 7, 2025.
(60) Provisional application No. 63/933,235, filed on Dec. 7, 2025.
(60) Provisional application No. 63/933,233, filed on Dec. 7, 2025.
(60) Provisional application No. 63/934,327, filed on Dec. 8, 2025.
(60) Provisional application No. 63/934,324, filed on Dec. 8, 2025.
(60) Provisional application No. 63/941,632, filed on Dec. 15, 2025.
(60) Provisional application No. 63/941,652, filed on Dec. 16, 2025.
(60) Provisional application No. 63/941,655, filed on Dec. 16, 2025.
(60) Provisional application No. 63/943,530, filed on Dec. 18, 2025.
(60) Provisional application No. 63/943,531, filed on Dec. 18, 2025.
(60) Provisional application No. 63/965,273, filed on Jan. 21, 2026.
(60) Provisional application No. 63/965,261, filed on Jan. 21, 2026.
(60) Provisional application No. 63/965,267, filed on Jan. 21, 2026.
(60) Provisional application No. 63/966,888, filed on Jan. 23, 2026.
(60) Provisional application No. 63/968,152, filed on Jan. 26, 2026.
(60) Provisional application No. 63/968,080, filed on Jan. 26, 2026.
(60) Provisional application No. 63/968,124, filed on Jan. 26, 2026.
(60) Provisional application No. 63/968,140, filed on Jan. 26, 2026.
(60) Provisional application No. 63/968,187, filed on Jan. 26, 2026.
(60) Provisional application No. 63/968,200, filed on Jan. 26, 2026.
(60) Provisional application No. 63/968,229, filed on Jan. 26, 2026.
(60) Provisional application No. 63/975,311, filed on Feb. 3, 2026.
(60) Provisional application No. 63/975,287, filed on Feb. 3, 2026.
(60) Provisional application No. 63/975,297, filed on Feb. 3, 2026.
(60) Provisional application No. 63/975,303, filed on Feb. 3, 2026.
(60) Provisional application No. 63/977,760, filed on Feb. 6, 2026.
(60) Provisional application No. 63/978,987, filed on Feb. 9, 2026.
(60) Provisional application No. 63/979,000, filed on Feb. 9, 2026.
(60) Provisional application No. 63/979,001, filed on Feb. 9, 2026.
(60) Provisional application No. 63/980,796, filed on Feb. 11, 2026.
(60) Provisional application No. 63/986,629, filed on Feb. 19, 2026.
(60) Provisional application No. 63/987,883, filed on Feb. 21, 2026.
(60) Provisional application No. 63/988,283, filed on Feb. 22, 2026.
(60) Provisional application No. 63/990,971, filed on Feb. 25, 2026.
(60) Provisional application No. 63/990,979, filed on Feb. 25, 2026.
(60) Provisional application No. 63/990,985, filed on Feb. 25, 2026.
(60) Provisional application No. 63/990,993, filed on Feb. 25, 2026.
(60) Provisional application No. 63/990,999, filed on Feb. 25, 2026.
(60) Provisional application No. 63/991,003, filed on Feb. 25, 2026.
(60) Provisional application No. 63/991,998, filed on Feb. 26, 2026.
(60) Provisional application No. 63/993,600, filed on Feb. 28, 2026.
(60) Provisional application No. 63/993,603, filed on Feb. 28, 2026.
(60) Provisional application No. 63/993,605, filed on Feb. 28, 2026.
(60) Provisional application No. 63/993,607, filed on Feb. 28, 2026.
(60) Provisional application No. 63/993,608, filed on Feb. 28, 2026.
(60) Provisional application No. 63/994,648, filed on Mar. 2, 2026.
(60) Provisional application No. 63/996,742, filed on Mar. 4, 2026.
(60) Provisional application No. 64/000,976, filed on Mar. 9, 2026.
(60) Provisional application No. 64/001,200, filed on Mar. 10, 2026.
(60) Provisional application No. 64/003,122, filed on Mar. 11, 2026.
(60) Provisional application No. 64/003,123, filed on Mar. 11, 2026.
(60) Provisional application No. 64/003,132, filed on Mar. 11, 2026.
(60) Provisional application No. 64/003,138, filed on Mar. 11, 2026.
(60) Provisional application No. 64/003,142, filed on Mar. 11, 2026.
(60) Provisional application No. 64/005,416, filed on Mar. 13, 2026.
(60) Provisional application No. 64/005,426, filed on Mar. 13, 2026.
(60) Provisional application No. 64/005,443, filed on Mar. 13, 2026.
(60) Provisional application No. 64/009,691, filed on Mar. 18, 2026.
(60) Provisional application No. 64/009,701, filed on Mar. 18, 2026.
(60) Provisional application No. 64/009,711, filed on Mar. 18, 2026.
(60) Provisional application No. 64/009,883, filed on Mar. 18, 2026.
(60) Provisional application No. 64/009,891, filed on Mar. 18, 2026.
(60) Provisional application No. 64/009,900, filed on Mar. 18, 2026.
(60) Provisional application No. 64/009,910, filed on Mar. 18, 2026.
(60) Provisional application No. 64/009,918, filed on Mar. 18, 2026.
(60) Provisional application No. 64/009,937, filed on Mar. 18, 2026.
(60) Provisional application No. 64/011,038, filed on Mar. 19, 2026.
(60) Provisional application No. 64/011,051, filed on Mar. 19, 2026.
(60) Provisional application No. 64/011,078, filed on Mar. 19, 2026.
(60) Provisional application No. 64/011,086, filed on Mar. 19, 2026.
(60) Provisional application No. 64/012,342, filed on Mar. 20, 2026.
(60) Provisional application No. 64/012,348, filed on Mar. 20, 2026.
(60) Provisional application No. 64/012,352, filed on Mar. 20, 2026.
(60) Provisional application No. 64/012,377, filed on Mar. 20, 2026.
(60) Provisional application No. 64/012,384, filed on Mar. 20, 2026.
(60) Provisional application No. 64/014,757, filed on Mar. 23, 2026.
(60) Provisional application No. 64/014,777, filed on Mar. 23, 2026.

(51) Int. Cl. H05K 7/20

(52) U.S. Cl. CPC H05K 7/2039

(57) ABSTRACT

A passive nanoscale cavity device comprising a substrate supporting one or more high-curvature geometric features, such as but not limited to frustums, cones, nanowires, ridges, or graphene edges, positioned opposite an opposing surface across a nanoscale gap. The high-curvature features create a confined cavity region in which electromagnetic mode trajectories differ substantially from those in parallel-plate geometries. The cavity geometry produces geometry-dependent forces and thermal energy redistribution effects without requiring electrical power, mechanical actuation, or active control. The geometric features are characterized by fabrication parameters including feature angle, gap spacing, tip radius, and feature density, which determine the device operating regime. Devices may be implemented as individual structures, arrays, or multilayer stacks, and may be integrated with electronic systems, sealed enclosures, or other systems requiring passive thermal management or nanoscale force generation.

### CROSS-REFERENCE TO RELATED APPLICATIONS

Priority is claimed in the application data sheet to the following patents or patent applications, each of which is expressly incorporated herein by reference in its entirety:
64/014,757
64/014,770
64/014,772
64/014,777
64/012,342
64/012,348
64/012,352
64/012,377
64/012,384
64/011,038
64/011,043
64/011,051
64/011,078
64/011,086
64/009,691
64/009,701
64/009,711
64/009,883
64/009,891
64/009,900
64/009,910
64/009,918
64/009,937
64/005,416
64/005,426
64/005,443
63/003,147
63/003,151
64/003,122
64/003,123
64/003,132
63/003,138
63/003,142
64/001,200
64/000,976
63/996,742
63/994,648
63/993,600
63/993,603
63/993,605
63/993,607
63/993,608
63/991,998
63/990,971
63/990,979
63/990,985
63/990,993
63/990,999
63/991,003
63/988,283
63/987,883
63/986,629
63/980,796
63/978,987
63/979,000
63/979,001
63/977,760
63/975,311
63/975,287
63/975,297
63/975,303
63/975,308
63/968,152
63/968,080
63/968,124
63/968,140
63/968,187
63/968,200
63/968,229
Ser. No. 19/458,428
63/941,632
63/933,237
63/933,225
63/930,614
63/928,801
63/927,212
63/927,196
63/926,434
63/926,417
63/926,413
63/926,411
63/924,573
63/924,600
63/924,560
63/966,888
63/965,273
63/965,261
63/965,267
63/943,530
63/943,531
63/941,652
63/941,655
63/934,327
63/934,324
63/933,240
63/933,227
63/933,233
63/933,235
63/931,463
63/928,796
63/928,805
63/928,808
63/928,813
63/928,819
63/928,823
63/927,181
63/927,187
63/927,189
63/927,202
63/927,208
63/926,390
63/926,392
63/926,397
63/926,405
63/926,421
63/926,425
63/926,430
63/924,566
63/924,554
63/923,021
63/923,014
63/921,275
63/921,271
63/921,288
63/921,276
63/921,280
63/919,475
63/919,479
63/916,455
63/916,458
63/916,468
63/916,471
63/916,473
63/916,983
63/916,439
63/915,125
63/915,129
63/915,133
63/915,136
63/915,138
63/901,866
63/902,501
63/901,823
63/901,826
63/901,834
63/901,636
63/901,638
63/901,640
63/901,644
63/901,646
63/901,649
63/874,637
63/874,639
63/874,640
63/874,641
63/870,101
63/870,103
63/870,096
63/870,098
63/869,452
63/869,434

### BACKGROUND OF THE INVENTION

### Field of the Art

The present invention is in the field of nanoscale cavity devices, and more particularly to devices comprising high-curvature geometric features separated by nanoscale gaps from opposing surfaces for geometry-dependent force generation and thermal energy redistribution.

### Discussion of the State of the Art

Thermal management at micro-and nanometer length scales presents persistent challenges in modern engineering systems. Conventional cooling approaches generally rely on macroscopic thermodynamic gradients and require either active energy input or external heat sinks. Examples include thermoelectric devices that require a temperature gradient or electrical current, mechanical refrigeration cycles, convective cooling using fluids, and radiative heat transfer to colder environments. While effective at larger scales, these techniques become increasingly difficult to implement in highly miniaturized systems, sealed environments, or applications where electrical power, mechanical motion, or external heat rejection pathways are unavailable or undesirable. None of these approaches is capable of reducing or redistributing thermal energy in an enclosed or thermally isolated cavity without some external sink or applied energy input.

Existing nanoscale structures designed for force generation, displacement sensing, or optical confinement include microelectromechanical systems (MEMS) and nanoelectromechanical systems (NEMS) devices such as accelerometers, pressure sensors, optical switches, thermoelectric energy harvesters, atomic force microscope tips, and nanoelectromechanical switches. Although such systems operate at nanometer scales, none are designed to exploit geometry-dependent electromagnetic interactions that arise when high-curvature structures are positioned at nanoscale separations from opposing surfaces.

Recent experimental investigations of re-entrant and tapered cavity geometries at nanoscale separations have revealed force magnitudes that differ significantly from predictions based on parallel-plate models. In such configurations, a tapered or re-entrant structure creates a cavity region with strongly varying boundary curvature. Experiments involving these geometries have reported forces several orders of magnitude larger than predicted for comparable gap sizes. The excess cannot be attributed to materials uncertainty, as independent numerical evaluations using state-of-the-art solvers converge on predictions consistent with standard theory while diverging from experiment by the same margin. The anomalous forces exhibit a distinct power-law dependence, insensitivity to material composition and temperature inconsistent with known electromagnetic models, and a purely geometry-dependent signature controlled by the macroscopic shape of the cavity boundaries rather than microscopic surface properties.

These observations suggest that sharply curved cavity boundaries and confined geometries can modify the electromagnetic mode structure within the cavity in ways not captured by models that assume smooth or planar boundaries. Certain cavity geometries may allow electromagnetic modes to follow complex trajectories within the cavity region, interacting repeatedly with cavity boundaries and potentially accumulating geometric phase or related effects as they propagate. Despite the growing body of experimental observations indicating that such geometry-dependent effects exist, there remains a lack of practical device architectures designed to intentionally exploit these interactions. Prior work in nanoscale thermal management and microelectromechanical systems has largely focused on conventional mechanisms such as conduction, radiation, and externally powered thermoelectric cooling. Existing technologies do not generally incorporate cavity geometries specifically engineered to modify electromagnetic mode trajectories in order to generate useful forces or passive thermal effects.

What is needed is a class of nanoscale cavity devices that utilize engineered high-curvature geometric features separated by nanoscale gaps from opposing surfaces to produce geometry-dependent forces and thermal energy redistribution effects, and that are capable of deployment in sealed, vacuum, cryogenic, or other environments where conventional thermal management techniques are impractical.

### SUMMARY OF THE INVENTION

Accordingly, the inventor has conceived and reduced to practice, a passive nanoscale cavity device with high-curvature geometric features. The present invention is a class of nanoscale cavity devices referred to herein as Passive Galvin Cells. A Passive Galvin Cell comprises one or more high-curvature geometric features supported by a substrate and positioned opposite an opposing surface across a nanoscale gap. The high-curvature geometric features and the opposing surface together define a confined cavity region in which electromagnetic vacuum fluctuations interact with the cavity boundaries. The geometric configuration of the cavity produces geometry-dependent forces and thermal energy redistribution effects that differ substantially from those produced by simple parallel-plate geometries.

The high-curvature geometric features may take a variety of forms including frustums, cones, nanowires, ridges, graphene edges, tapered posts, and fractal or hierarchical structures. These features create regions of strongly varying boundary curvature within the cavity, which influence the trajectories of electromagnetic modes propagating within the cavity region. In certain geometries, the cavity configuration may support electromagnetic trajectories that cannot be continuously contracted within the accessible cavity region. Such trajectories may accumulate geometric phase during repeated circulation within the cavity, giving rise to large geometry-dependent forces or enhanced pathways for thermal energy redistribution.

The behavior of a Passive Galvin Cell is governed primarily by geometric parameters that are set during fabrication. The feature angle, defined as the angle between the edge of a high-curvature geometric feature and a plane parallel to the substrate, is the primary parameter determining the device operating regime. Additional parameters including nanogap spacing, feature height, tip radius, and feature density may be selected to optimize device performance for a target application. Adjustment of these parameters produces distinct operating regimes ranging from a far-subcritical regime in which device behavior closely resembles conventional parallel-plate interactions, through near-critical and supercritical regimes in which geometry-dependent forces increase rapidly and may approach a plateau value, to a far-supercritical regime in which large forces are accompanied by thermal energy redistribution within the cavity.

The opposing surface may be implemented as a rigid plate, a thin membrane, a suspended film, or another structural layer. In many embodiments, the opposing surface serves as the thermal interface between the cavity device and an external object, enclosure, or fluid medium requiring thermal management. Thermal energy entering the device through this interface interacts with the confined cavity region and may be redistributed through geometry-mediated processes associated with the confined electromagnetic modes.

Passive Galvin Cells operate without externally applied electrical power, electromagnetic drive fields, or mechanical actuation. The physical effects produced by the device arise from the static geometry of the cavity and the nanoscale separation between its boundaries. This passive operation makes the devices suitable for deployment in environments where active cooling systems are impractical, including sealed enclosures, vacuum systems, cryogenic environments, microelectronic packages, and sensor housings.

The devices may be implemented as individual structures, periodic or graded arrays, or multilayer stacks. Array configurations allow many nanoscale cavities to operate simultaneously, producing cumulative forces or thermal effects at macroscopic scales. Multilayer configurations allow multiple cavity regions to be stacked vertically within a compact structure. The devices may be fabricated using established microfabrication and nanofabrication techniques including but not limited to photolithography, electron-beam lithography, anisotropic etching, reactive ion etching, nanoimprint lithography, atomic layer deposition, chemical vapor deposition, and two-dimensional material transfer processes.

According to an embodiment, A passive nanoscale cavity device comprising: a structured substrate; one or more high-curvature geometric features extending from the structured substrate, each high-curvature geometric feature having a feature angle defined between an edge of the high-curvature geometric feature and a plane parallel to a surface of the structured substrate; an opposing substrate positioned opposite the one or more high-curvature geometric features; a nanogap between a tip of at least one of the one or more high-curvature geometric features and the opposing substrate; one or more substrate supports between the structured substrate and the opposing substrate configured to maintain the nanogap; and a cavity region defined between cell walls of the one or more high-curvature geometric features and the opposing substrate, the cavity region configured to support electromagnetic mode trajectories that produce geometry-dependent forces and thermal energy redistribution effects, wherein the device operates passively without externally applied electrical power, electromagnetic drive fields, or mechanical actuation, is disclosed.

### BRIEF DESCRIPTION OF THE DRAWING FIGURES

FIG. 1 is a cross-sectional diagram illustrating an exemplary system architecture for a Passive Galvin Cell device.

FIG. 2 is a cross-sectional diagram illustrating an exemplary system architecture for a Passive Galvin Cell device configured with a feature array comprising multiple fabricated features distributed across a structured substrate.

FIG. 3 is a cross-sectional diagram illustrating an exemplary system architecture for a Passive Galvin Cell device configured with fabricated features at different feature angles to produce spatially varying operating regimes across the device surface.

FIG. 4 is a cross-sectional diagram illustrating an exemplary system architecture for a Passive Galvin Cell device configured with an array of far-supercritical features thermally coupled to a heat source through a thermal interface for passive thermal energy redistribution.

FIG. 5 is a diagram illustrating exemplary high-curvature geometric feature variants that may be employed in Passive Galvin Cell devices, showing four representative feature geometries extending from structured substrate.

FIG. 6 is a flow diagram illustrating an exemplary method for fabricating a Passive Galvin Cell device.

FIG. 7 is a flow diagram illustrating an exemplary method for deploying a Passive Galvin Cell device for passive thermal management.

FIG. 8 illustrates an exemplary computing environment on which an embodiment described herein may be implemented.

### DETAILED DESCRIPTION OF THE INVENTION

The inventor has conceived, and reduced to practice, a passive nanoscale cavity device with high-curvature geometric features. Recent experimental observations have revealed anomalous behaviors in certain nanoscale geometries involving sharp features and nanometer-scale gaps. These include deviations from theoretical predictions of near-field radiative models, Casimir-based force laws, or standard electromagnetic mode structures. Of particular significance are recent measurements involving re-entrant cavity geometries coupled to acoustic membranes, where forces exhibiting unusual scaling behavior and magnitude were observed. Such geometries demonstrated force magnitudes five orders of magnitude larger than parallel-plate Casimir predictions at comparable gap sizes, with a distinct power-law dependence on gap size.

The parallel-plate Casimir configuration represents a well-understood regime where measured forces between flat, parallel conducting plates follow an inverse-quartic dependence on separation distance. This regime has been validated across materials, temperatures, pressures, and surface treatments, producing reproducible results consistent with quantum electrodynamic predictions. However, when one plate is replaced by a tapered, frustum-like surface with the gap reduced into the ten to two thousand nanometer range, measured forces depart dramatically from expected Casimir behavior. Multiple experiments using frustum-plate geometries have reported force magnitudes five orders of magnitude larger than parallel-plate Casimir predictions, with a distinct power-law dependence characterized by an inverse-cubic rather than inverse-quartic scaling, insensitivity to material composition and temperature inconsistent with known electromagnetic models, and a purely geometry-dependent signature controlled by macroscopic shape rather than microscopic surface properties.

Conventional models generally treat the vacuum response as a weak perturbation governed by smooth boundaries and small geometric gradients. As a result, they do not fully describe how sharply varying boundary curvature influences the redistribution of confined field energy or how geometry may activate additional transfer pathways. The well-known Casimir effect, for example, already demonstrates that the vacuum can act as an effective curvature-related reservoir that mediates stresses between conductive boundaries. In that setting, the magnitude and sign of the force depend on the geometry of the surrounding structure, and energy is redistributed between electromagnetic fields and vacuum degrees of freedom.

The present invention is a class of nanoscale cavity devices referred to herein as Passive Galvin Cells. In the most general sense, a Passive Galvin Cell is a device comprising one or more high-curvature geometric features supported by a substrate and positioned opposite an opposing surface across a nanoscale gap. The high-curvature geometric features and the opposing surface together define a confined cavity region. The geometric configuration of the cavity influences the electromagnetic mode trajectories within the cavity region, producing geometry-dependent forces and thermal energy redistribution effects that differ substantially from those produced by simple parallel-plate geometries.

The devices described herein operate passively. The physical effects produced by the device arise from the static geometry of the cavity and the nanoscale separation between its boundaries. No externally applied electrical power, electromagnetic drive fields, mechanical actuation, or active control signals are required during device operation. Once fabricated and assembled, the device produces its characteristic force and thermal redistribution behavior as an inherent consequence of its geometric structure.

The operation of the devices disclosed herein does not depend on any particular theoretical explanation of the underlying physical mechanisms. The structural configurations described herein are defined by their geometric and material properties and are capable of producing the described device behaviors regardless of the specific physical interpretation adopted. Theoretical references and physical descriptions provided herein are included for context and to aid understanding, but are not intended to limit the scope of the claimed structures.

A representative Passive Galvin Cell includes the following structural elements: a substrate or structural support layer; one or more high-curvature geometric features extending from the substrate; an opposing surface, membrane, or thin film surface positioned above the features; a nanoscale gap separating the high-curvature geometric features from the opposing surface; and support structures or spacers configured to maintain the gap during operation.

The region between the high-curvature geometric features and the opposing surface forms a confined cavity in which electromagnetic fields and vacuum fluctuations interact with the cavity boundaries. The geometric configuration of this cavity strongly influences the behavior of electromagnetic modes within the region.

In many embodiments the high-curvature geometric features take the form of a tapered or re-entrant structure such as a frustum, cone, ridge, or nanowire. These structures create regions of high local curvature and spatially varying cavity thickness, which influence the trajectories of electromagnetic modes propagating within the cavity. The lateral surfaces of these features define the cell walls of the cavity region.

The opposing surface may be implemented as a rigid plate, a thin membrane, a suspended film, or another structural layer capable of maintaining a stable nanoscale separation from the high-curvature geometric features. In some embodiments the opposing surface also serves as the thermal interface between the device and an external object, enclosure, or fluid medium.

The cavity region formed between the high-curvature geometric features and the opposing surface may support electromagnetic mode trajectories that differ substantially from those found in simple parallel-plate cavities. In particular, the presence of tapered or re-entrant structures can cause electromagnetic modes to follow curved or looping paths within the cavity as they reflect from the cavity boundaries.

In certain geometries these trajectories may repeatedly circulate within the cavity before escaping, effectively producing multiple round-trip interactions with the cavity boundaries. The resulting behavior can generate forces or energy redistribution effects that depend strongly on the geometry of the cavity.

In some embodiments the cavity geometry may permit electromagnetic trajectories that cannot be continuously contracted within the accessible cavity region. Such trajectories may accumulate geometric phase during repeated circulation. These behaviors can produce large geometry-dependent forces or enhanced pathways for entropy or energy redistribution within the device.

In a parallel-plate cavity, electromagnetic modes travel in straight paths perpendicular to the plates. The round-trip path of each mode is contractible and no geometric phase accumulates. When one or both cavity boundaries are replaced by high-curvature geometric features, the electromagnetic mode trajectories are deflected at each interaction with the curved boundary. The wavevector of a mode propagating within the cavity traces a path in momentum space whose shape depends on the geometry of the cavity boundaries. For high-curvature features such as frustums or cones, the wavevector path may enclose a non-zero solid angle in momentum space during each round trip. This enclosed solid angle corresponds to a geometric phase accumulated by the mode, analogous to the Berry phase observed in optical fiber experiments.

The magnitude of the accumulated geometric phase depends on the feature angle and the overall geometry of the cavity. Shallow feature angles produce small wavevector deflections and correspondingly small geometric phase per round trip, while steep feature angles produce large deflections and large accumulated geometric phase. This relationship between feature angle and geometric phase is the physical basis for the operating regime dependence on feature angle described below.

The feature angle is defined as the angle between an edge of the high-curvature geometric feature and a plane parallel to a surface of the structured substrate. In embodiments using frustum or conical features, this is the angle between the sloped edge of the feature and a plane parallel to a surface of the structure substrate. The feature angle is the primary parameter determining the device operating regime. Shallow feature angles produce cavity geometries that more closely resemble parallel-plate configurations, while larger feature angles create strongly re-entrant cavities with more complex mode trajectories. The feature angle is set during fabrication by the etch profile, mask geometry, growth conditions, or deposition angle used to form the high-curvature features.

The nanogap is the separation distance between the high-curvature geometric features and the opposing surface. Typical gap values may range from approximately 1 nm to approximately 5000 nm depending on the device embodiment. In many embodiments the gap may be maintained within a narrower range such as approximately 1 nm to 200 nm. The nanogap spacing influences the strength of the interactions within the cavity. Smaller gap values generally increase confinement of electromagnetic modes and may enhance geometry-dependent forces and thermal effects. Larger gaps may reduce the magnitude of these effects but may simplify fabrication and improve mechanical robustness. The nanogap is set during fabrication by the height of spacer structures or the thickness of sacrificial layers.

In many embodiments the Passive Galvin Cell operates as an interface device positioned between a target object or enclosed region and the nanoscale cavity geometry. Thermal energy entering the device through the opposing surface interacts with the confined cavity region defined by the high-curvature geometric features.

The opposing membrane or plate of the device may be placed in direct thermal contact with an object or connected through a thermally conductive interface material. Examples of objects that may be thermally coupled to the device include microelectronic devices, sensor assemblies, optical components, microelectromechanical systems, and scientific instruments. Thermal energy from the object is conducted into the membrane or plate, where it interacts with the cavity region. From a system perspective this interaction may appear as a redistribution or reduction of thermal energy within the object.

The device may also be integrated into the wall or interior of an enclosed cavity, with the opposing membrane facing the interior of the enclosure. Thermal energy within the enclosed space may reach the membrane through thermal radiation, gas conduction, convective heat transfer, or molecular heat transfer in low-pressure environments.

Passive Galvin Cells are particularly well suited for operation in vacuum or low-pressure environments. In such environments convective heat transfer is suppressed and thermal energy transfer occurs primarily through radiation or conduction through structural components. The nanoscale cavity structure allows geometry-mediated interactions to occur even in the absence of gas-mediated heat transfer.

The structures described above may be implemented not only as individual cavities but also as arrays of cavities across a substrate. In array configurations each high-curvature geometric feature and its opposing surface region forms a small cavity, and many such cavities operate simultaneously across the device. Array configurations increase the total force or thermal redistribution capability of the device by multiplying the number of active cavity regions. Arrays may be fabricated using periodic, quasi-periodic, or graded patterns of high-curvature features.

In some embodiments multiple cavity layers may be stacked vertically. A first membrane may serve as the opposing surface for a lower cavity while simultaneously supporting a second high-curvature geometric feature that forms a second cavity with a second membrane above it. Multilayer configurations allow the device to create multiple interacting cavity regions within a single compact structure, enhancing the total force or thermal redistribution capability.

Large-area arrays may be particularly useful for applications such as cooling panels for electronic systems, thermal stabilization surfaces for scientific instruments, passive cooling elements within sealed enclosures, and nanoscale force generation arrays.

Passive Galvin Cell devices may be fabricated using established microfabrication and nanofabrication techniques commonly employed in semiconductor processing, microelectromechanical systems fabrication, and nanoscale materials synthesis.

Fabrication typically begins with preparation of a substrate. Suitable substrates include silicon wafers, silicon nitride films, silicon carbide wafers, sapphire substrates, metallic substrates, or multilayer composite structures. Substrates may be cleaned and planarized using standard semiconductor processing techniques.

High-curvature geometric features may be formed using a variety of techniques including photolithographic patterning followed by etching, electron-beam lithography, focused-ion-beam milling, anisotropic wet etching of crystalline substrates, reactive ion etching, and nanoimprint lithography. Nanowire structures may be fabricated using vapor-liquid-solid growth, template-assisted deposition, or other bottom-up synthesis techniques. Fractal or hierarchical geometries may be produced through multi-step lithographic patterning, self-assembly processes, or controlled etching techniques.

Spacer structures may be fabricated on the substrate to maintain the nanoscale gap. Spacers may take the form of pillars, ridges, walls, or other support structures. Spacer height may be precisely controlled using thin-film deposition techniques such as atomic layer deposition, which allows thickness control at the nanometer scale. Alternatively, sacrificial layers may be deposited and later removed to create a controlled gap.

The opposing surface may be fabricated as a thin membrane using chemical vapor deposition, plasma-enhanced chemical vapor deposition, atomic layer deposition, sputter deposition, or evaporation of thin metallic films. Two-dimensional materials such as graphene may be grown on a separate substrate and transferred onto the device structure. The membrane and substrate may be assembled using direct bonding, anodic bonding, adhesive bonding, or van der Waals bonding. Care may be taken during assembly to avoid membrane collapse due to capillary forces, using techniques such as critical point drying.

Devices may be fabricated individually or as arrays on a single substrate using large-area fabrication techniques such as photolithography, nanoimprint lithography, or interference lithography. Following fabrication, wafers may be diced into individual devices or retained as large-area arrays depending on the intended application.

### DEFINITIONS

As used herein, “nanoscale” means objects or features with at least one dimension roughly in the range of 1 nanometer to thousands of nanometers.

As used herein, “nanogap” means a separation distance between two surfaces roughly in the range of 1 nanometer to 5000 nanometers.

As used herein, “high-curvature geometric feature” means a structural feature exhibiting high local curvature or sharp geometric variation relative to a planar surface, including but not limited to frustums, cones, nanowires, ridges, graphene edges, tapered posts, and fractal or hierarchical structures.

As used herein, “feature angle” means the angle between an edge of the high-curvature geometric feature and a plane parallel to a surface of the structured substrate.

As used herein, “opposing surface” means a plate, membrane, thin film, or other structural layer positioned across a nanogap from a high-curvature geometric feature to form one boundary of a cavity region.

As used herein, “cavity region” means the space enclosed between a high-curvature geometric feature and an opposing surface in which electromagnetic modes may propagate and interact with the cavity boundaries.

As used herein, “cell wall” means a lateral boundary of the cavity region defined by the surfaces of the high-curvature geometric feature that enclose or partially enclose the cavity, distinct from the opposing surface.

As used herein, “passive” means operating without externally applied electrical power, electromagnetic drive fields, mechanical actuation, or active control signals.

As used herein, “Passive Galvin Cell” means a nanoscale cavity device comprising one or more high-curvature geometric features separated from an opposing surface by a nanogap, configured to produce geometry-dependent forces and thermal energy redistribution effects through passive operation.

As used herein, “operating regime” means a range of geometric configurations, characterized primarily by feature angle and nanogap spacing, within which the device exhibits qualitatively similar force and thermal redistribution behavior.

As used herein, “geometry-dependent force” means a force arising from the interaction of electromagnetic vacuum fluctuations with the boundary geometry of a nanoscale cavity, the magnitude and character of which depend on the shape of the cavity boundaries rather than solely on the separation distance or material properties.

### DETAILED DESCRIPTION OF DRAWING FIGURES

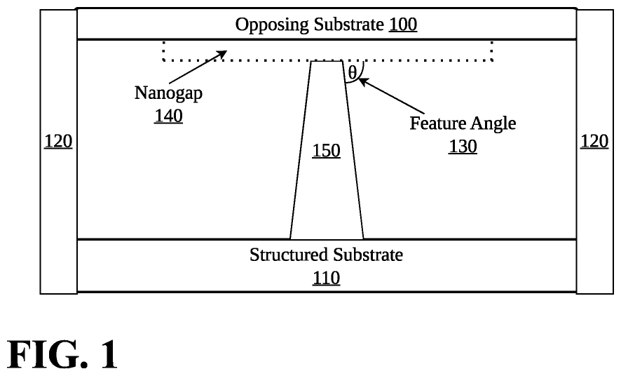

FIG. 1 is a cross-sectional diagram illustrating an exemplary system architecture for a Passive Galvin Cell device. The figure depicts the fundamental structural relationships among the components that define a nanoscale cavity device in which engineered high-curvature geometric features create confined electromagnetic mode trajectories within a nanogap cavity region, producing geometry-dependent forces and thermal energy redistribution effects.

A Passive Galvin Cell comprises an opposing substrate 100 positioned above a structured substrate 110 with a nanogap 140 separating the two substrates. Structured substrate 110 supports one or more fabricated features 150 that extend upward from the substrate surface toward opposing substrate 100. Substrate supports 120 are positioned on either side of fabricated features 150 to maintain nanogap 140 at a controlled separation distance between the apex of fabricated features 150 and the underside of opposing substrate 100. A feature angle 130 is defined between the edge of fabricated features 150 and the axis perpendicular to the surface of structured substrate 110. Together, these structural elements define a confined cavity region between the cell walls of fabricated features 150 and the underside of opposing substrate 100 in which electromagnetic vacuum fluctuations interact with the cavity boundaries to produce geometry-dependent physical effects.

Fabricated features 150 are high-curvature geometric structures that serve as the primary functional elements of the Passive Galvin Cell. The lateral surfaces of fabricated features 150 define the cell walls of the cavity region. In the embodiment shown in FIG. 1, fabricated features 150 take the form of tapered structures having a wider base at structured substrate 110 and a narrower tip approaching opposing substrate 100. The taper of fabricated features 150 creates a cavity region with spatially varying thickness, which influences the trajectories of electromagnetic modes propagating within the cavity. The region of closest approach between fabricated features 150 and opposing substrate 100 occurs at the tip of fabricated features 150, where the local curvature is highest and electromagnetic mode confinement is strongest.

Although FIG. 1 depicts fabricated features 150 as tapered frustum-like structures, it should be understood that fabricated features 150 may take a variety of structural forms while maintaining the fundamental principle of creating high-curvature boundaries within the nanogap cavity. In exemplary embodiments, fabricated features 150 may comprise truncated conical or pyramidal frustums, conical structures terminating in a pointed or rounded apex, high-aspect-ratio nanowires grown using vapor-liquid-solid or template-assisted deposition processes, ridge structures extending linearly across structured substrate 110, graphene edges or other two-dimensional material edges exhibiting atomic-scale sharpness, or fractal and hierarchical structures exhibiting multiple levels of geometric detail. The selection of geometry for fabricated features 150 may depend on the target operating regime, the desired magnitude of geometry-dependent forces, and the fabrication techniques available. In some exemplary embodiments, different regions of structured substrate 110 may employ different geometries for fabricated features 150 in order to tailor device behavior across the substrate surface.

Fabricated features 150 may be formed using a variety of established microfabrication and nanofabrication techniques. In exemplary embodiments, frustum or pyramidal features may be fabricated by photolithographic patterning of a resist mask on structured substrate 110 followed by anisotropic etching to create the tapered profile. Conical tips may be produced by focused-ion-beam milling, isotropic etching, or oxidation sharpening processes. Nanowire structures may be fabricated using bottom-up synthesis techniques in which catalyst particles deposited on structured substrate 110 guide the growth of nanowires extending vertically from the substrate surface. Graphene-edge features may be formed by patterning graphene ribbons or networks on structured substrate 110 using lithographic techniques, with the exposed edges serving as the high-curvature geometric features. Ridge features may be produced using interference lithography, nanoimprint lithography, or anisotropic etching techniques. Fractal or hierarchical structures may be produced through multi-step lithographic patterning, repeated deposition and etching cycles, or self-assembly processes. Additional fabrication techniques including electron-beam lithography, reactive ion etching, and directional deposition may also be employed depending on the required feature dimensions and geometry.

The local curvature at the tip of fabricated features 150 plays an important role in determining the electromagnetic mode structure in the vicinity of the tip. This curvature may be characterized by a tip radius parameter. Smaller radii of curvature produce stronger curvature concentration and may increase the magnitude of geometry-dependent interactions within the cavity. In exemplary embodiments, the tip radius of fabricated features 150 may range from atomic-scale dimensions, as may be achieved with graphene edges, to several tens of nanometers for lithographically defined frustum or conical features. The tip radius, together with feature angle 130 and nanogap 140, contributes to determining the operating regime and force magnitude of the device.

Feature angle 130 is the angle between the edge of fabricated features 150 and a plane parallel to the surface of structured substrate 110. Feature angle 130 is the primary geometric parameter governing the operating regime of the Passive Galvin Cell and is fixed during fabrication by the etch profile, mask geometry, growth conditions, or deposition angle used to form fabricated features 150. When feature angle 130 is zero, the cell walls of fabricated features 150 would be vertical and the cavity geometry would resemble a parallel-plate configuration. As feature angle 130 increases from zero, the cell walls of fabricated features 150 tilt outward, creating a tapered cavity region with increasingly complex electromagnetic mode trajectories.

The physical significance of feature angle 130 relates to how it shapes the electromagnetic mode trajectories within the cavity region. In a parallel-plate cavity where feature angle 130 would be zero, electromagnetic modes travel in straight paths perpendicular to the plates. The round-trip path of each mode is contractible and no geometric phase accumulates during mode circulation. When feature angle 130 is greater than zero, as shown in FIG. 1, electromagnetic modes propagating within the cavity are deflected at each interaction with the cell walls of fabricated features 150. Each deflection changes the direction of the mode's wavevector. Over the course of a complete round trip within the cavity, the wavevector traces a closed path in momentum space. The shape of this closed path depends on feature angle 130: larger feature angles produce larger deflections at each boundary interaction, causing the wavevector path to enclose a greater solid angle on the momentum-space sphere.

The solid angle enclosed by the wavevector path during each round trip corresponds to a geometric phase accumulated by the mode, analogous to the Berry phase observed experimentally in optical fiber systems. This geometric phase is gauge-invariant, depends only on the geometry of the mode trajectory rather than on the local field amplitude, and is independent of the material composition of the cavity boundaries. The magnitude of the accumulated geometric phase increases monotonically with feature angle 130. This increasing geometric phase per round trip is the physical mechanism through which feature angle 130 controls the operating regime of the device and determines the magnitude of geometry-dependent forces and thermal redistribution effects.

The value of feature angle 130 places the device into one of several qualitatively distinct operating regimes. In a far-subcritical regime, where feature angle 130 is small (in exemplary embodiments approximately 20 degrees to 30 degrees), the cavity geometry closely resembles a parallel-plate configuration, the accumulated geometric phase per round trip is small, and the device exhibits relatively weak geometry-dependent effects. In a subcritical regime, where feature angle 130 is moderate (in exemplary embodiments approximately 30 degrees to 45 degrees), the cavity departs from the parallel-plate configuration and geometry-dependent forces grow relative to the far-subcritical regime. In a near-critical regime, where feature angle 130 approaches a critical value (in exemplary embodiments approximately 45 degrees, though the precise value depends on nanogap 140 spacing and cavity dimensions), the magnitude of geometry-dependent forces may increase rapidly and device behavior may become highly sensitive to small variations in geometric parameters. In a supercritical regime, where feature angle 130 exceeds the critical value (in exemplary embodiments approximately 45 degrees to 50 degrees), the device may produce large geometry-dependent forces that may approach a plateau value. In a far-supercritical regime, where feature angle 130 is large (in exemplary embodiments approximately 60 degrees to 85 degrees), the device may remain within the force plateau while simultaneously exhibiting passive thermal energy redistribution effects within the cavity region. These regime boundaries are illustrative and may shift depending on combinations of nanogap 140 spacing, cavity dimensions, feature height, and material properties.

Substrate supports 120 are structural elements that maintain nanogap 140 at a predetermined separation distance during device operation. As shown in FIG. 1, substrate supports 120 are positioned on either side of fabricated features 150, extending from structured substrate 110 to the underside of opposing substrate 100. The height of substrate supports 120 directly determines the dimension of nanogap 140 and is therefore a critical fabrication parameter. Substrate supports 120 may take the form of pillars, walls, ridges, or other support structures positioned around or among fabricated features 150. In exemplary embodiments, substrate supports 120 may be fabricated using lithographic patterning followed by deposition or etching. The height of substrate supports 120 may be precisely controlled using thin-film deposition techniques such as atomic layer deposition, which allows thickness control at the nanometer scale. In alternative exemplary embodiments, substrate supports 120 may be formed by depositing a sacrificial layer of controlled thickness on structured substrate 110 prior to bonding of opposing substrate 100, with the sacrificial material subsequently removed to release nanogap 140. Care may be taken during sacrificial layer removal to avoid collapse of opposing substrate 100 onto fabricated features 150 due to capillary forces, using techniques such as critical point drying or supercritical fluid drying.

Nanogap 140 is the separation distance between the tip of fabricated features 150 and the underside of opposing substrate 100. Nanogap 140 defines the region of closest approach between the two substrates and is where electromagnetic mode confinement is strongest. In exemplary embodiments, nanogap 140 may range from approximately 1 nm to approximately 5000 nm depending on the device embodiment. In many exemplary embodiments nanogap 140 may be maintained within a narrower range such as approximately 1 nm to 200 nm, where geometry-dependent forces are most pronounced.

The dimension of nanogap 140, in combination with feature angle 130, determines the operating regime of the device. Smaller values of nanogap 140 generally increase confinement of electromagnetic modes within the cavity region and may enhance geometry-dependent forces and thermal redistribution effects. Larger values of nanogap 140 may reduce the magnitude of these effects but may simplify fabrication, improve mechanical robustness, and reduce the risk of membrane collapse or stiction. The relationship between nanogap 140 spacing and the critical feature angle at which the device transitions between operating regimes means that the precise regime boundaries depend on the combination of both parameters rather than on either parameter alone. In exemplary embodiments, a device with a larger nanogap 140 may require a correspondingly larger feature angle 130 to achieve the same operating regime as a device with a smaller nanogap 140.

Opposing substrate 100 serves as the upper boundary of the cavity region and forms one of the two primary surfaces between which geometry-dependent electromagnetic interactions occur. Opposing substrate 100 may be implemented as a rigid plate, a thin membrane, a suspended film, or a multilayer composite structure depending on the intended application. In exemplary embodiments, opposing substrate 100 may be fabricated from metallic materials such as aluminum, gold, or copper; semiconductor materials such as silicon or silicon carbide; dielectric materials such as silicon nitride, silicon dioxide, or sapphire; carbon-based materials such as graphene or diamond-like carbon; or multilayer composite structures incorporating combinations of these materials.

In embodiments employing conductive materials for opposing substrate 100, the cavity geometry may function as a nanoscale electromagnetic cavity in which electromagnetic fields reflect repeatedly between opposing substrate 100 and the cell walls of fabricated features 150. In embodiments employing dielectric or semiconductor materials, the electromagnetic boundary response of opposing substrate 100 may be determined by dielectric permittivity, surface impedance, or other material parameters rather than by electrical conductivity alone. The operation of the device does not require any specific material for opposing substrate 100 and is compatible with any material system capable of forming a nanoscale cavity boundary that influences electromagnetic mode trajectories within the cavity region.

In embodiments where the Passive Galvin Cell is used for thermal management applications, opposing substrate 100 may serve as the thermal interface between the cavity device and an external object, enclosure, or fluid medium requiring passive cooling or thermal stabilization. In such configurations, opposing substrate 100 may be placed in direct thermal contact with the target object or connected through a thermally conductive interface material. Examples of objects that may be thermally coupled to opposing substrate 100 include microelectronic devices, sensor assemblies, optical components, microelectromechanical systems, and scientific instruments. Thermal energy from the target object is conducted into opposing substrate 100, where it enters the cavity region defined by fabricated features 150 and interacts with the confined electromagnetic modes. From a system perspective this interaction may appear as a redistribution or reduction of thermal energy within the coupled object.

In exemplary embodiments where opposing substrate 100 is implemented as a thin membrane, the membrane may be fabricated using chemical vapor deposition, plasma-enhanced chemical vapor deposition, atomic layer deposition, sputter deposition, or evaporation of thin metallic films. Two-dimensional materials such as graphene may be grown on a separate substrate and transferred onto the device structure using established transfer techniques. Membrane thickness may range from several nanometers to several hundred nanometers depending on the material and application. Thin membrane implementations may be advantageous when the device is used for thermal management, as the thin membrane provides a low thermal resistance pathway between the target object and the cavity region.

In some exemplary embodiments, opposing substrate 100 may be flexible or deformable rather than strictly rigid. Flexible implementations of opposing substrate 100 may allow the cavity geometry to adapt slightly to mechanical stresses, thermal expansion, or fabrication variations while maintaining nanogap 140. This flexibility may be advantageous in systems that experience mechanical vibration or thermal cycling during operation.

Structured substrate 110 provides the structural foundation from which fabricated features 150 and substrate supports 120 extend. Structured substrate 110 may comprise silicon wafers, silicon nitride films, silicon carbide wafers, sapphire substrates, metallic substrates, or multilayer composite structures. In exemplary embodiments, structured substrate 110 may be prepared using standard semiconductor cleaning procedures to remove organic contaminants, oxide layers, and particulate matter, including RCA cleaning, solvent cleaning, oxygen plasma treatment, or other surface preparation techniques suitable for the chosen substrate material. The surface of structured substrate 110 may also be planarized using polishing or chemical-mechanical planarization processes to achieve the flatness required for maintaining uniform nanoscale gaps across the device area.

Material selection for structured substrate 110 may be guided by considerations including mechanical stability, compatibility with microfabrication techniques used to form fabricated features 150, thermal conductivity, electrical conductivity, chemical stability, and compatibility with the intended operating environment. In exemplary embodiments where fabricated features 150 are formed by anisotropic etching, structured substrate 110 may comprise a crystalline material such as silicon whose crystal planes provide natural etch stop surfaces for controlling the geometry of fabricated features 150.

The assembly of the Passive Galvin Cell shown in FIG. 1 involves bonding opposing substrate 100 to substrate supports 120 after fabricated features 150 and substrate supports 120 have been formed on structured substrate 110. In exemplary embodiments, this bonding may be accomplished using direct bonding, anodic bonding, adhesive bonding, or van der Waals bonding in the case of atomically thin materials. In embodiments using sacrificial layers to define nanogap 140, the sacrificial material may be removed after bonding of opposing substrate 100 to create a free-standing cavity gap between opposing substrate 100 and fabricated features 150. Techniques such as critical point drying or supercritical fluid drying may be employed during sacrificial layer removal to prevent stiction during removal of liquids from the cavity region.

The Passive Galvin Cell device shown in FIG. 1 operates passively once fabricated and assembled. All geometric parameters including feature angle 130, nanogap 140, the dimensions and geometry of fabricated features 150, and the height of substrate supports 120 are fixed during manufacturing. No externally applied electrical power, electromagnetic drive fields, mechanical actuation, or active control signals are required during device operation. The geometry-dependent forces and thermal energy redistribution effects produced by the device arise as inherent consequences of the static cavity geometry and the nanoscale separation between opposing substrate 100 and fabricated features 150. This passive operation makes the device suitable for deployment in environments where active cooling systems or mechanically driven devices are impractical, including sealed enclosures, vacuum systems, cryogenic environments, microelectronic packages, and sensor housings.

Although FIG. 1 depicts a configuration in which fabricated features 150 extend from structured substrate 110 toward a planar opposing substrate 100, it should be understood that in alternative exemplary embodiments, high-curvature geometric features may be present on both sides of the cavity. For example, fabricated features 150 on structured substrate 110 may face a second set of high-curvature features formed on or attached to opposing substrate 100. Such bilateral configurations may produce complex cavity geometries in which electromagnetic mode trajectories interact with multiple curved surfaces during circulation within the cavity. Representative bilateral configurations include a nanowire tip facing a ridge structure, a frustum facing a conical feature, a graphene edge facing a nanowire tip, or a ridge array facing a fractal surface.

While FIG. 1 depicts a single-cavity device for clarity, it should be understood that the architecture shown may be extended to array and multilayer configurations. In array implementations, multiple fabricated features 150 may be distributed across structured substrate 110 in periodic, quasi-periodic, or graded patterns. Each fabricated feature 150 and its corresponding region of opposing substrate 100 forms a small cavity, and many such cavities may operate simultaneously across the device to produce cumulative geometry-dependent forces and thermal redistribution effects at macroscopic scales. In multilayer implementations, opposing substrate 100 of one cavity layer may serve as structured substrate 110 for a second cavity layer above it, allowing multiple interacting cavity regions to be stacked vertically within a compact structure.

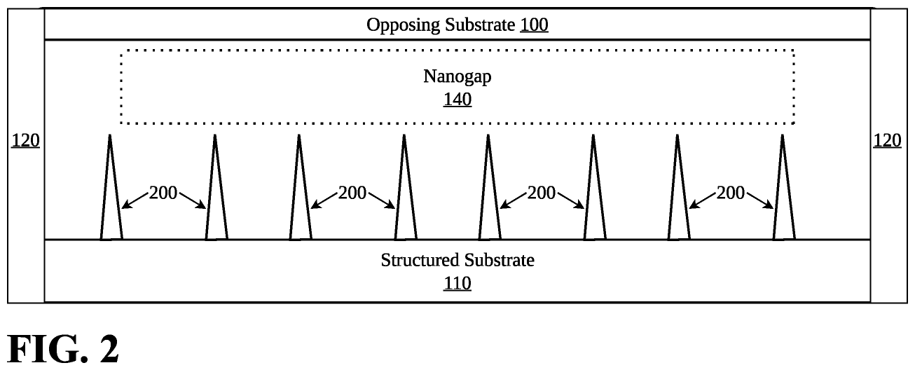

FIG. 2 is a cross-sectional diagram illustrating an exemplary system architecture for a Passive Galvin Cell device configured with a feature array comprising multiple fabricated features distributed across a structured substrate. The device comprises opposing substrate 100 positioned above structured substrate 110 with nanogap 140 maintained between the two substrates by substrate supports 120. A feature array 200 extends from the surface of structured substrate 110 toward opposing substrate 100. Feature array 200 comprises a plurality of individual high-curvature geometric features arranged in a spatial pattern across structured substrate 110. Each individual feature within feature array 200 creates a localized cavity region with opposing substrate 100, and the collective operation of all cavity regions across feature array 200 produces cumulative geometry-dependent forces and thermal energy redistribution effects.

Feature array 200 may be arranged in a variety of spatial configurations depending on the intended application and fabrication process. In exemplary embodiments, the individual features within feature array 200 may be distributed as a periodic array in which the features are spaced at uniform intervals across structured substrate 110. Periodic arrangements simplify fabrication using techniques such as photolithography, interference lithography, or nanoimprint lithography, and produce uniform device behavior across the substrate surface. In alternative exemplary embodiments, feature array 200 may be arranged as a quasi-periodic array in which the spacing varies gradually across the substrate, or as a graded array in which the feature geometry, height, or feature angle changes progressively from one region of the substrate to another. Graded configurations may be used to tailor the distribution of geometry-dependent forces or thermal redistribution effects across the device surface, for example to concentrate cooling effects in a localized region corresponding to a thermal hotspot on a coupled electronic device.

The individual features within feature array 200 may take any of the high-curvature geometric forms described in connection with FIG. 1, including frustums, cones, nanowires, ridges, graphene edges, or fractal and hierarchical structures. In the embodiment shown in FIG. 2, feature array 200 comprises tapered frustum-like structures, though it should be understood that this geometry is exemplary and not limiting. In some exemplary embodiments, all features within feature array 200 may share the same geometry and dimensions, producing uniform cavity behavior across the device. In alternative exemplary embodiments, feature array 200 may incorporate features of different geometries, heights, or feature angles within the same array. For example, a central region of feature array 200 may employ frustum features at a supercritical feature angle for maximum force generation while a peripheral region employs shallower features at a subcritical feature angle, creating a spatially varying force and thermal redistribution profile across the device.

The spacing between individual features within feature array 200 is another design parameter that influences device behavior. Feature spacing may range from tens of nanometers to tens of micrometers depending on the application, the geometry of the individual features, and the fabrication technique employed. Denser feature spacing within feature array 200 produces a larger number of active cavity regions per unit area of structured substrate 110, which increases the cumulative force generation and thermal redistribution capability of the device. However, the spacing must be sufficient to allow each individual feature to form a distinct cavity region with opposing substrate 100 without interference from neighboring features. In exemplary embodiments where feature array 200 comprises frustum or conical features, the minimum spacing between adjacent features is determined by the base diameter of each feature plus sufficient clearance for the electromagnetic mode trajectories within each cavity to circulate without significant coupling to adjacent cavities. In exemplary embodiments where feature array 200 comprises nanowire structures, feature spacing may be substantially smaller due to the small footprint of each nanowire, allowing very high feature densities to be achieved. Nanowire forest implementations of feature array 200 are particularly useful when large-area device implementations are desired, as they allow many high-curvature features to be fabricated simultaneously across structured substrate 110 using bottom-up synthesis techniques such as vapor-liquid-solid growth or template-assisted deposition.

The fabrication of feature array 200 may leverage large-area patterning techniques that are well established in semiconductor processing. In exemplary embodiments, the spatial pattern of feature array 200 may be defined using photolithographic patterning, in which a resist mask is applied to structured substrate 110 and exposed through a photomask defining the array layout. Subsequent etching, deposition, or growth steps produce the individual features at the locations defined by the mask. Interference lithography may be used to create large-area periodic patterns without a physical mask, which may be advantageous for producing uniform feature arrays over wafer-scale areas. Nanoimprint lithography may be used to replicate a master pattern onto structured substrate 110 with high throughput and sub-wavelength resolution. Electron-beam lithography may be employed when high-resolution, non-periodic, or custom array patterns are required. Following fabrication of feature array 200, wafers may be diced into individual devices or retained as large-area arrays depending on the intended application.

Each individual feature within feature array 200 has an associated feature angle as described in connection with FIG. 1. In the embodiment shown in FIG. 2, the feature angle is uniform across feature array 200, meaning all features share the same taper geometry and the device operates in a single operating regime across its entire surface. In alternative exemplary embodiments, the feature angle may vary across feature array 200 to produce spatially varying operating conditions. The collective feature angle of feature array 200, together with nanogap 140, determines the operating regime of the device as a whole. Because feature array 200 comprises many individual cavity regions operating in parallel, the total geometry-dependent force produced by the device scales approximately with the number of features in the array multiplied by the force contribution per feature. This scaling relationship allows Passive Galvin Cell devices configured with feature array 200 to produce macroscopic forces and thermal redistribution effects even though each individual cavity region is nanoscale in size.

Substrate supports 120 in the embodiment of FIG. 2 are positioned at the periphery of feature array 200 to maintain nanogap 140 across the full extent of the array. In some exemplary embodiments, additional substrate supports 120 may be distributed among the individual features of feature array 200 to provide mechanical stability across large-area devices and to prevent sagging or deformation of opposing substrate 100 between the peripheral supports. The height of substrate supports 120 determines nanogap 140 as described in connection with FIG. 1.

Opposing substrate 100 in the embodiment of FIG. 2 spans the full extent of feature array 200 and may be implemented as a rigid plate or a thin membrane as described in connection with FIG. 1. In thermal management applications, opposing substrate 100 serves as the thermal interface through which thermal energy from an external heat source enters the device and interacts with the plurality of cavity regions defined by feature array 200. The large surface area of opposing substrate 100 in an array configuration provides a correspondingly large thermal coupling area, which may be advantageous when the device is thermally coupled to objects with distributed heat generation such as integrated circuit packages or power electronic modules.

The architecture shown in FIG. 2 may be extended to multilayer stacked configurations in which opposing substrate 100 of one array layer serves as structured substrate 110 of a second array layer above it. In such configurations, a first feature array 200 on a lower structured substrate 110 faces a first opposing substrate 100, which simultaneously supports a second feature array 200 facing a second opposing substrate 100 above it. Multilayer stacked implementations allow the device to create multiple interacting cavity layers within a single compact structure, further increasing the cumulative force and thermal redistribution capability of the device. The number of stacked layers may be selected based on the target application and the mechanical and thermal constraints of the overall system.

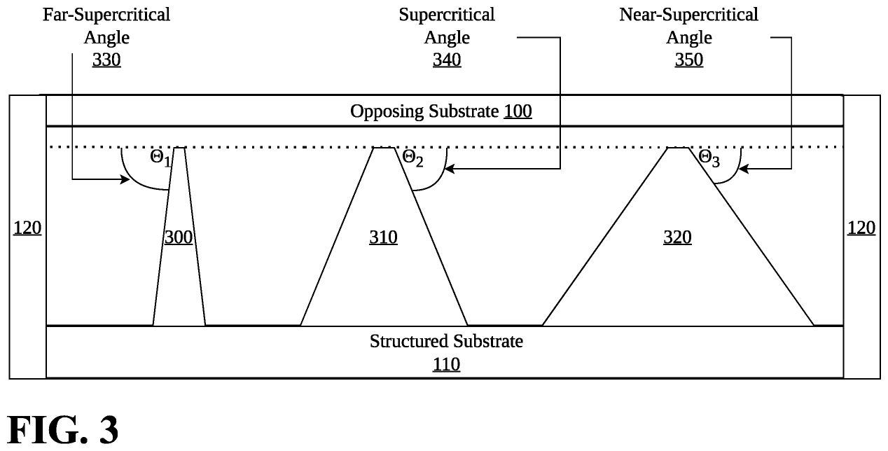

FIG. 3 is a cross-sectional diagram illustrating an exemplary system architecture for a Passive Galvin Cell device configured with fabricated features at different feature angles to produce spatially varying operating regimes across the device surface. In an embodiment the device comprises opposing substrate 100 positioned above structured substrate 110 with substrate supports 120 maintaining the separation between the two substrates. Three fabricated features extend from the surface of structured substrate 110 toward opposing substrate 100, each formed at a different feature angle to operate in a distinct regime. A far-supercritical feature 300 is formed at a first feature angle theta-1, a supercritical feature 310 is formed at a second feature angle theta-2, and a near-critical feature 320 is formed at a third feature angle theta-3. The three features are arranged across structured substrate 110 to create a spatial gradient of operating regimes, though it should be understood that the number of features, their arrangement, and the specific combination of operating regimes shown are exemplary and not limiting.

Far-supercritical feature 300 is the fabricated feature within the device having the largest feature angle, designated theta-1. A far-supercritical angle 330 identifies the operating regime associated with far-supercritical feature 300. In exemplary embodiments, the feature angle of far-supercritical feature 300 may be approximately 60 degrees to 85 degrees, though the precise value depends on the nanogap spacing and cavity dimensions. At this feature angle, the cell walls of far-supercritical feature 300 are steeply tapered, creating a deeply re-entrant cavity region in which electromagnetic mode trajectories enclose a large solid angle in momentum space during each round trip. The accumulated geometric phase per round trip is correspondingly large. In this regime, far-supercritical feature 300 may produce strong geometry-dependent forces that have reached a plateau value, meaning further increases in feature angle do not substantially increase force magnitude. Additionally, far-supercritical feature 300 may simultaneously exhibit passive thermal energy redistribution effects within its cavity region. Far-supercritical feature 300 therefore operates at the most aggressive operating point within the device, where both force generation and thermal redistribution are active.

Supercritical feature 310 is the fabricated feature having a moderate-to-large feature angle, designated theta-2. A supercritical angle 340 identifies the operating regime associated with supercritical feature 310. In exemplary embodiments, the feature angle of supercritical feature 310 may be approximately 45 degrees to 50 degrees. At this feature angle, supercritical feature 310 produces large geometry-dependent forces within its localized cavity region. The accumulated geometric phase per round trip exceeds the critical threshold, and the force magnitude may approach or enter the plateau regime. However, the degree of thermal energy redistribution at supercritical feature 310 may be less pronounced than at far-supercritical feature 300 because the excess geometric phase above the critical value is smaller. Supercritical feature 310 therefore operates in a regime dominated by strong force generation with the onset of thermal redistribution effects.

Near-critical feature 320 is the fabricated feature having the smallest feature angle of the three features shown, designated theta-3. A near-critical angle 350 identifies the operating regime associated with near-critical feature 320. In exemplary embodiments, the feature angle of near-critical feature 320 may be approximately 45 degrees, though the precise critical value depends on the nanogap spacing and cavity dimensions as described in connection with FIG. 1. At this feature angle, the behavior of near-critical feature 320 is highly sensitive to small variations in geometric parameters. The accumulated geometric phase per round trip is approaching the critical value at which geometry-dependent forces increase rapidly. Small changes in feature angle, nanogap spacing, or cavity dimensions near this operating point may produce disproportionately large changes in device behavior. Near-critical feature 320 therefore operates in a transitional regime between the subcritical domain, where geometry-dependent effects are modest, and the supercritical domain, where forces are large and may plateau.

The progression from near-critical feature 320 through supercritical feature 310 to far-supercritical feature 300 creates a spatial gradient of operating regimes across the surface of structured substrate 110. The region of the device containing far-supercritical feature 300 produces the largest forces and the strongest thermal redistribution effects. The region containing near-critical feature 320 produces rapidly increasing but not yet saturated forces with minimal thermal redistribution. The region containing supercritical feature 310 produces intermediate behavior between these two extremes.

This spatially graded architecture provides several design advantages over uniform feature arrays as described in connection with FIG. 2. In exemplary embodiments where the device is thermally coupled to an electronic component through opposing substrate 100, the graded architecture allows the device designer to match the spatial distribution of cooling effects to the spatial distribution of heat generation on the electronic component. For example, a thermal hotspot on an integrated circuit may be positioned opposite far-supercritical feature 300 where thermal redistribution effects are strongest, while cooler regions of the circuit are positioned opposite supercritical feature 310 or near-critical feature 320 where thermal redistribution is less pronounced but geometry-dependent forces still contribute to overall device performance. This spatial matching between the thermal load profile and the operating regime profile allows the graded device to provide more efficient thermal management than a uniform array operating at a single feature angle across its entire surface.

In alternative exemplary embodiments, the device may comprise more than three fabricated features at distinct feature angles, producing a finer gradient of operating regimes across the device surface. The feature angles may also span a wider range of operating regimes than the three shown in FIG. 3. For example, a graded device may include features ranging from far-subcritical angles of approximately 20 degrees through near-critical, supercritical, and far-supercritical angles up to approximately 85 degrees, creating a comprehensive gradient across the full range of operating regimes. In further exemplary embodiments, the feature angle may vary continuously rather than in discrete steps, producing a smooth gradient of operating conditions across structured substrate 110. Such continuous gradients may be achieved through fabrication techniques that allow progressive variation of etch depth or taper angle across the substrate, such as gray-scale lithography or variable-dose electron-beam exposure.

The individual features within the graded architecture may take any of the high-curvature geometric forms described in connection with FIGS. 1 and 2, including frustums, cones, nanowires, ridges, graphene edges, or fractal structures. In the embodiment shown in FIG. 3, far-supercritical feature 300, supercritical feature 310, and near-critical feature 320 are depicted as tapered frustum-like structures with different taper angles, though it should be understood that the grading principle applies equally to other feature geometries. In some exemplary embodiments, the graded device may incorporate not only variation in feature angle but also variation in feature geometry across structured substrate 110. For example, far-supercritical feature 300 may employ a frustum geometry optimized for the far-supercritical regime, while near-critical feature 320 may employ a conical or nanowire geometry that provides finer geometric control near the critical transition.

Substrate supports 120 in the embodiment of FIG. 3 maintain the separation between opposing substrate 100 and structured substrate 110 across the full extent of the device. Because far-supercritical feature 300, supercritical feature 310, and near-critical feature 320 have different feature angles and therefore different base widths and taper profiles, the geometry of the cavity region varies across the device. In exemplary embodiments, the height of all fabricated features may be uniform so that the tips of far-supercritical feature 300, supercritical feature 310, and near-critical feature 320 all approach opposing substrate 100 at approximately the same nanogap distance. In alternative exemplary embodiments, the feature heights may be adjusted so that the nanogap varies in coordination with the feature angle, providing an additional degree of design freedom for tuning the operating regime at each position across the device.

The architecture shown in FIG. 3 may be extended to multilayer stacked configurations as described in connection with FIG. 2, in which opposing substrate 100 of one layer serves as structured substrate 110 of a second layer above it. In such configurations, the feature angle distributions of adjacent layers may be aligned, inverted, or offset relative to one another to produce complex three-dimensional distributions of operating regimes within the stacked device. The graded architecture may also be combined with the uniform array architecture of FIG. 2, for example by using a uniform array at a single supercritical angle as a baseline layer with a graded arrangement of far-supercritical feature 300, supercritical feature 310, and near-critical feature 320 as a supplementary layer to provide spatially targeted thermal management.

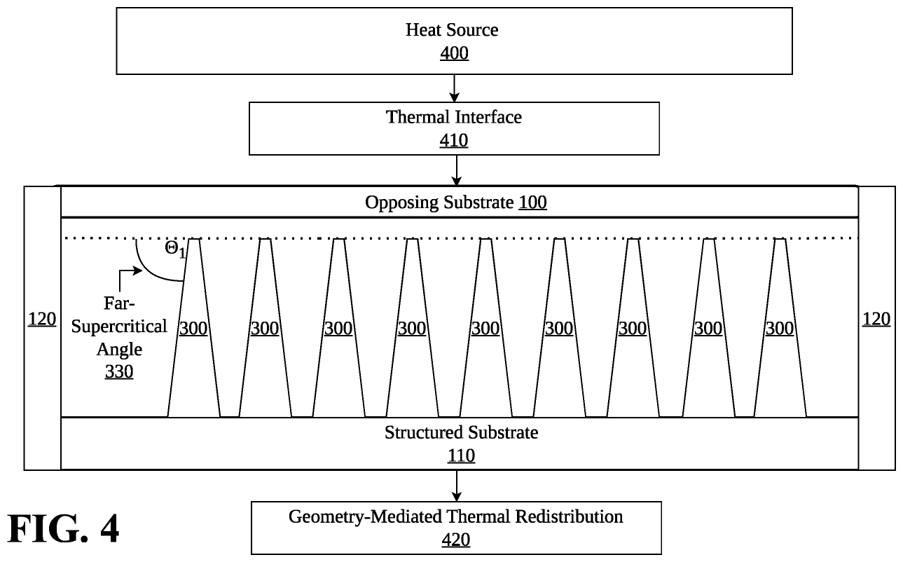

FIG. 4 is a cross-sectional diagram illustrating an exemplary system architecture for a Passive Galvin Cell device configured with an array of far-supercritical features thermally coupled to a heat source through a thermal interface for passive thermal energy redistribution. In an embodiment, the device comprises opposing substrate 100 positioned above structured substrate 110 with substrate supports 120 maintaining the separation between the two substrates. An array of far-supercritical features 300 extends from the surface of structured substrate 110 toward opposing substrate 100. Each far-supercritical feature 300 within the array is formed at a first feature angle theta-1 corresponding to a far-supercritical angle 330, as described in connection with FIG. 3. A heat source 400 is positioned above opposing substrate 100 and is thermally coupled to opposing substrate 100 through a thermal interface 410. Thermal energy generated by heat source 400 passes through thermal interface 410 into opposing substrate 100, enters the cavity regions defined by the array of far-supercritical features 300, and undergoes geometry-mediated thermal redistribution 420 through the device.

Heat source 400 is the object or system component from which thermal energy originates and for which passive thermal management is desired. Heat source 400 may comprise any object that generates or contains thermal energy and that benefits from passive cooling or thermal stabilization. In exemplary embodiments, heat source 400 may be a microelectronic device such as a microprocessor, application-specific integrated circuit, power amplifier, or memory module. In alternative exemplary embodiments, heat source 400 may be a sensor assembly, an optical component such as a laser diode or photodetector, a microelectromechanical system, a scientific instrument, or any other component that produces waste heat during operation. Heat source 400 may also be an enclosed cavity or chamber containing a fluid or gas at elevated temperature, a cryogenic system in which even small thermal loads must be managed, or a sealed enclosure in which conventional convective or radiative cooling pathways are unavailable. The Passive Galvin Cell architecture shown in FIG. 4 is agnostic to the specific nature of heat source 400 and is compatible with any thermal load that can be placed in thermal proximity to opposing substrate 100.

Thermal interface 410 is the structural and thermal pathway between heat source 400 and opposing substrate 100. Thermal interface 410 provides mechanical coupling between heat source 400 and the Passive Galvin Cell while ensuring efficient thermal energy transfer from heat source 400 into the cavity region of the device. In exemplary embodiments, thermal interface 410 may comprise a direct physical contact between heat source 400 and opposing substrate 100, in which the two surfaces are placed in intimate contact so that thermal conduction occurs directly across the interface. In alternative exemplary embodiments, thermal interface 410 may comprise a thermally conductive interface material positioned between heat source 400 and opposing substrate 100. Representative interface materials include thermal greases, thermal pastes, thermally conductive adhesives, indium foils, graphite pads, or other thermal interface materials commonly used in electronic packaging. In further exemplary embodiments where heat source 400 is an enclosed cavity or chamber rather than a solid object, thermal interface 410 may represent the thermal pathway through which energy reaches opposing substrate 100 via thermal radiation, gas conduction, convective heat transfer, or molecular heat transfer in low-pressure environments. The specific implementation of thermal interface 410 may be selected based on the thermal conductivity requirements of the application, the mechanical constraints of the system, and the compatibility of the interface material with the operating environment.

The array of far-supercritical features 300 shown in FIG. 4 is configured so that all fabricated features within the array share the same feature angle theta-1 at far-supercritical angle 330. As described in connection with FIG. 3, far-supercritical angle 330 corresponds to feature angles in exemplary embodiments of approximately 60 degrees to 85 degrees, at which the device operates in a regime where geometry-dependent forces have reached a plateau value and passive thermal energy redistribution effects are active within the cavity region. By configuring the entire array at far-supercritical angle 330, the device shown in FIG. 4 maximizes the thermal redistribution capability across the full area of the device, making this configuration particularly well suited for thermal management applications where the primary objective is passive cooling or thermal stabilization of heat source 400.

The use of a uniform array of far-supercritical features 300 rather than a graded array as described in connection with FIG. 3 may be advantageous when heat source 400 presents a substantially uniform thermal load across its surface. In such cases, there is no need for spatial variation in the operating regime because the thermal management requirements are the same at every point across the device. The uniform far-supercritical configuration provides the maximum thermal redistribution rate per unit area of the device and simplifies fabrication by requiring only a single feature angle across the entire array. In alternative exemplary embodiments where heat source 400 presents a non-uniform thermal load, the uniform far-supercritical array of FIG. 4 may be combined with or replaced by the graded architecture of FIG. 3 to provide spatially targeted thermal management.

Geometry-mediated thermal redistribution 420 represents the physical process by which thermal energy entering the cavity region through opposing substrate 100 is redistributed through interactions with the confined electromagnetic modes within the cavities defined by far-supercritical features 300. Thermal energy conducted through thermal interface 410 and into opposing substrate 100 enters the nanogap cavity regions where it interacts with the electromagnetic mode structure shaped by the high-curvature cell walls of far-supercritical features 300. In the far-supercritical regime, the electromagnetic mode trajectories within each cavity enclose large solid angles in momentum space during each round trip, accumulating substantial geometric phase. The excess geometric phase above the critical threshold is associated with enhanced pathways for energy redistribution within the cavity. From a system perspective, geometry-mediated thermal redistribution 420 may manifest as a reduction or redistribution of thermal energy within heat source 400 or within the enclosed space thermally coupled to the device.

It should be noted that the operation of geometry-mediated thermal redistribution 420 does not depend on any particular theoretical explanation of the underlying physical mechanism. The structural configuration of far-supercritical features 300 at far-supercritical angle 330 separated from opposing substrate 100 by the nanogap is sufficient to produce the described thermal redistribution behavior regardless of the specific physical interpretation adopted. Theoretical descriptions provided herein, including references to geometric phase, electromagnetic mode trajectories, and momentum-space solid angles, are included for context and to aid understanding but are not intended to limit the scope of the claimed structures or their operation.

The magnitude of geometry-mediated thermal redistribution 420 scales with the number of far-supercritical features 300 in the array and with the total active cavity area of the device. Denser arrays of far-supercritical features 300 provide more active cavity regions per unit area of structured substrate 110, increasing the cumulative thermal redistribution rate. In exemplary embodiments, the array may comprise tens, hundreds, thousands, or more individual far-supercritical features 300 distributed across structured substrate 110 depending on the substrate area, the feature dimensions, and the thermal management requirements of the application. Large-area implementations may be fabricated using wafer-scale patterning techniques such as photolithography, interference lithography, or nanoimprint lithography as described in connection with FIG. 2.

Opposing substrate 100 in the embodiment of FIG. 4 serves a dual role as both the upper boundary of the cavity regions defined by far-supercritical features 300 and the thermal interface surface through which thermal energy from heat source 400 enters the device. In exemplary embodiments where thermal performance is a primary design objective, opposing substrate 100 may be implemented as a thin membrane fabricated from a material with high thermal conductivity, such as a metallic thin film, graphene, or diamond-like carbon, to minimize the thermal resistance between heat source 400 and the cavity region. In alternative exemplary embodiments where mechanical robustness is prioritized, opposing substrate 100 may be implemented as a rigid plate of silicon, silicon carbide, or sapphire, which provides structural stability at the expense of somewhat higher thermal resistance.

The Passive Galvin Cell device shown in FIG. 4 operates passively once fabricated, assembled, and thermally coupled to heat source 400 through thermal interface 410. No externally applied electrical power, electromagnetic drive fields, mechanical actuation, or active control signals are required during operation. The thermal redistribution process occurs continuously as a consequence of the static cavity geometry and the nanoscale separation between opposing substrate 100 and far-supercritical features 300. This passive operation makes the device particularly suitable for deployment in environments where active cooling systems are impractical, including sealed enclosures where convective cooling is unavailable, vacuum systems where gas-mediated heat transfer is suppressed, cryogenic environments where active cooling introduces unwanted thermal loads, microelectronic packages where space and power constraints preclude active cooling, and sensor housings where mechanical vibration from active cooling systems would interfere with measurement accuracy.

The architecture shown in FIG. 4 may be extended to multilayer stacked configurations in which multiple cavity layers are arranged vertically between heat source 400 and the exterior of the device. In such configurations, each layer comprises an array of far-supercritical features 300 facing an opposing substrate 100, and the opposing substrate 100 of one layer serves as structured substrate 110 of the next layer. Stacked configurations allow the device to process thermal energy through multiple sequential cavity interactions, which may increase the total thermal redistribution capability of the device within a compact vertical footprint. The number of stacked layers may be selected based on the thermal load presented by heat source 400 and the mechanical and dimensional constraints of the overall system.

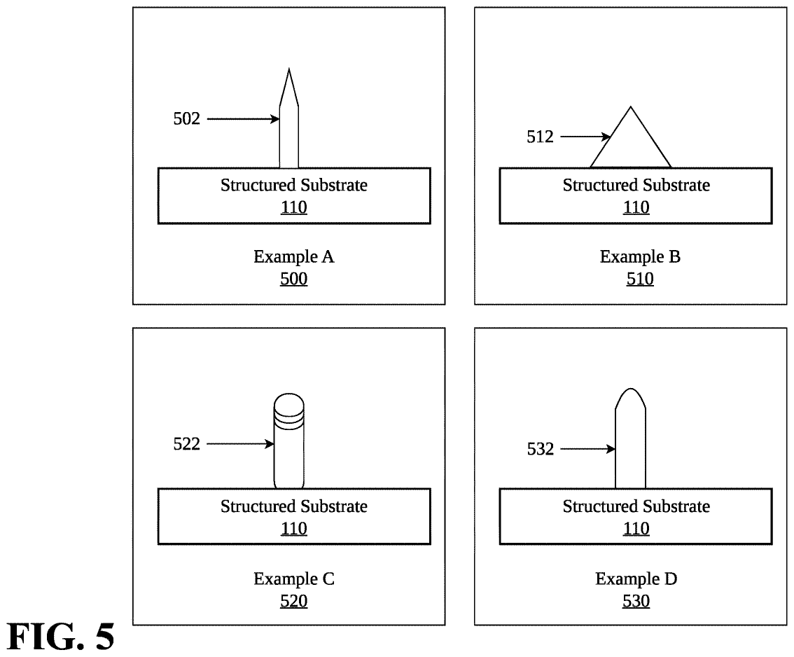

FIG. 5 is a diagram illustrating exemplary high-curvature geometric feature variants that may be employed in Passive Galvin Cell devices, showing four representative feature geometries extending from structured substrate. As shown in FIG. 5, four exemplary feature geometries are depicted, each extending from a respective structured substrate 110. An example A 500 depicts a pointed spire feature 502. An example B 510 depicts a triangular feature 512. An example C 520 depicts a cylindrical feature 522. An example D 530 depicts a rounded spire feature 532. Each of these feature geometries represents a different structural approach to creating high-curvature boundaries within a nanogap cavity, and each produces distinct electromagnetic mode trajectory characteristics within the cavity region when positioned opposite an opposing substrate as described in connection with FIGS. 1 through 4. It should be understood that the four geometries shown in FIG. 5 are representative and non-limiting, and that numerous additional feature geometries may be employed while maintaining the fundamental principle of creating confined electromagnetic mode trajectories within a nanoscale cavity.

Example A 500 illustrates a pointed spire feature 502 extending from structured substrate 110. Pointed spire feature 502 is a high-aspect-ratio structure that tapers continuously from a wider base at structured substrate 110 to a sharp apex. The apex of pointed spire feature 502 may achieve very small radii of curvature, potentially approaching atomic-scale sharpness depending on the fabrication technique employed. The sharp tip produces strong curvature concentration in the region of closest approach to an opposing substrate, where electromagnetic mode confinement is most intense. The continuously tapering profile of pointed spire feature 502 creates a cavity region in which the separation between the cell wall and the opposing substrate varies smoothly with height, producing a gradient of electromagnetic mode confinement from the base to the tip. In exemplary embodiments, pointed spire feature 502 may be fabricated using focused-ion-beam milling, which allows precise sculpting of the taper profile and tip geometry. In alternative exemplary embodiments, pointed spire feature 502 may be produced using isotropic etching of a masked substrate followed by oxidation sharpening, a process in which thermal oxidation preferentially consumes material near the tip to produce an extremely sharp apex. Vapor-liquid-solid nanowire growth processes may also produce pointed spire geometries when growth conditions are controlled to create a tapering profile along the nanowire length. The feature angle of pointed spire feature 502 is defined between the edge of the spire and the axis perpendicular to structured substrate 110 as described in connection with FIG. 1, and may be selected to place the device in any of the operating regimes described in connection with FIG. 3.

Example B 510 illustrates a triangular feature 512 extending from structured substrate 110. Triangular feature 512 has a cross-sectional profile characterized by straight, angled edges converging from a wide base to a narrow apex, forming a triangular or wedge-shaped geometry. Unlike the continuously curving profile of pointed spire feature 502, the cell walls of triangular feature 512 are substantially planar, meeting at a defined angle at the apex. This geometry creates a cavity region with linearly varying separation between the cell wall and an opposing substrate, producing a well-defined feature angle that is constant along the full height of the feature. The planar cell walls of triangular feature 512 produce electromagnetic mode trajectories with consistent deflection angles at each boundary interaction, which may simplify the analysis and prediction of device behavior for a given feature angle. In exemplary embodiments, triangular feature 512 may be fabricated using anisotropic wet etching of crystalline substrates such as silicon, where the etch rate depends on crystal orientation and naturally produces planar surfaces along specific crystal planes.

Example C 520 illustrates a cylindrical feature 522 extending from structured substrate 110. Cylindrical feature 522 is a high-aspect-ratio structure with substantially vertical sidewalls and a flat or slightly rounded upper surface. Unlike the tapered geometries of pointed spire feature 502 and triangular feature 512, the cell walls of cylindrical feature 522 are substantially parallel to the axis perpendicular to structured substrate 110, giving cylindrical feature 522 a feature angle approaching zero along its sidewalls. The high-curvature regions of cylindrical feature 522 are concentrated at the upper edges where the vertical sidewall meets the top surface, creating localized regions of strong curvature enhancement at the rim of the cylinder. These edge regions produce electromagnetic mode deflections in the cavity between the top of cylindrical feature 522 and an opposing substrate. The cavity region directly above cylindrical feature 522 may resemble a parallel-plate geometry with a very small gap, while the cavity region along the sidewalls of cylindrical feature 522 is substantially different in character. In exemplary embodiments, cylindrical feature 522 may be fabricated using deep reactive ion etching processes that produce high-aspect-ratio structures with substantially vertical sidewalls. In alternative exemplary embodiments, cylindrical feature 522 may be produced by electroplating into a lithographically defined template, by directional deposition through a shadow mask, or by etching a mesa structure using an etch process with high anisotropy. Cylindrical feature 522 may be advantageous in applications where a large flat top surface area is desired in close proximity to the opposing substrate, as the flat top surface of cylindrical feature 522 provides a uniform nanogap region directly above the feature while the high-curvature edges provide the geometry-dependent electromagnetic mode interactions.

Example D 530 illustrates a rounded spire feature 532 extending from structured substrate 110. Rounded spire feature 532 is a tapered structure similar in overall profile to pointed spire feature 502 but terminating in a rounded or hemispherical apex rather than a sharp point. The rounded tip of rounded spire feature 532 has a finite and controlled radius of curvature, which may range from several nanometers to tens of nanometers depending on the fabrication process. The rounded apex produces a localized region of high but finite curvature concentration, in contrast to the potentially atomic-scale sharpness achievable with pointed spire feature 502. The finite tip radius of rounded spire feature 532 may provide more reproducible device behavior from unit to unit because the tip geometry is less sensitive to nanometer-scale fabrication variations than a sharply pointed apex. The tapering profile of rounded spire feature 532 creates a cavity region with smoothly varying separation between the cell wall and an opposing substrate, similar to pointed spire feature 502, but the electromagnetic mode structure in the immediate vicinity of the tip differs due to the finite curvature at the apex. In exemplary embodiments, rounded spire feature 532 may be fabricated by first forming a pointed structure using any of the techniques described for pointed spire feature 502 and subsequently rounding the tip through a controlled isotropic etch, thermal oxidation followed by oxide removal, or ion bombardment at glancing angles. In alternative exemplary embodiments, rounded spire feature 532 may be produced directly by deposition or growth processes that naturally terminate in a rounded geometry.

In addition to the four exemplary geometries shown in FIG. 5, numerous other high-curvature geometric feature variants may be employed in Passive Galvin Cell devices. In exemplary embodiments, the high-curvature geometric features may comprise frustum structures, which are truncated conical or pyramidal features having a flat top surface of finite width as described in connection with FIG. 1. Frustum structures combine a tapered cavity region along the cell walls with a parallel-plate-like region above the flat tip, and offer the advantage of straightforward fabrication using established anisotropic etching techniques with controlled etch depth.

In further exemplary embodiments, the high-curvature geometric features may comprise nanowire structures grown using vapor-liquid-solid growth processes, template-assisted deposition, or other bottom-up synthesis techniques. Nanowire tips provide localized curvature enhancement at extremely small feature footprints and may be arranged as dense arrays or nanowire forests across structured substrate 110. Nanowire forest implementations are particularly useful when large-area device implementations are desired, as they allow many high-curvature features to be fabricated simultaneously across the substrate without requiring individual lithographic patterning of each feature.

In further exemplary embodiments, the high-curvature geometric features may comprise graphene edges or other two-dimensional material edges exhibiting atomic-scale sharpness. The edges of graphene sheets represent extremely high-curvature boundary features with edge radii on the order of a single atomic layer. Graphene edges may be oriented vertically toward an opposing substrate to create nanoscale cavity regions in which the edge acts as the high-curvature geometric feature. Graphene edges may be patterned as ribbons, networks, or arrays on structured substrate 110 using lithographic techniques developed for graphene device fabrication.

In further exemplary embodiments, the high-curvature geometric features may comprise ridge or linear feature geometries extending across the surface of structured substrate 110. Ridge structures create a line of enhanced curvature along the crest of each ridge and may be fabricated using anisotropic etching, interference lithography, nanoimprint techniques, or other surface patterning methods. Ridge arrays are particularly useful for creating large-area devices in which the cavity geometry repeats in one dimension across the substrate.

In further exemplary embodiments, the high-curvature geometric features may comprise fractal or hierarchical structures exhibiting multiple levels of geometric detail. A fractal feature may comprise a primary tapered structure supporting secondary smaller features at its apex, which in turn may support tertiary features at an even smaller scale. Such multi-scale structures produce curvature enhancement across multiple spatial scales simultaneously, which may influence a broader range of electromagnetic mode wavelengths within the cavity. Hierarchical structures may also increase the tolerance of the device to small variations in nanogap spacing or fabrication imperfections, because curvature enhancement occurs at multiple length scales rather than being concentrated at a single feature dimension.

In further exemplary embodiments, combinations of the above geometries may be employed within a single device. For example, a device may incorporate pointed spire features 502 in one region of structured substrate 110 and rounded spire features 532 in another region, or may combine nanowire forests with ridge structures, or may superimpose fractal sub-features on top of triangular features 512 or cylindrical features 522. Different regions of structured substrate 110 may employ different feature geometries in order to tailor the electromagnetic mode behavior and the resulting device performance across the substrate surface. The selection of feature geometry may be guided by the target operating regime, the available fabrication processes, the required uniformity of device behavior, and the mechanical and thermal constraints of the intended application.

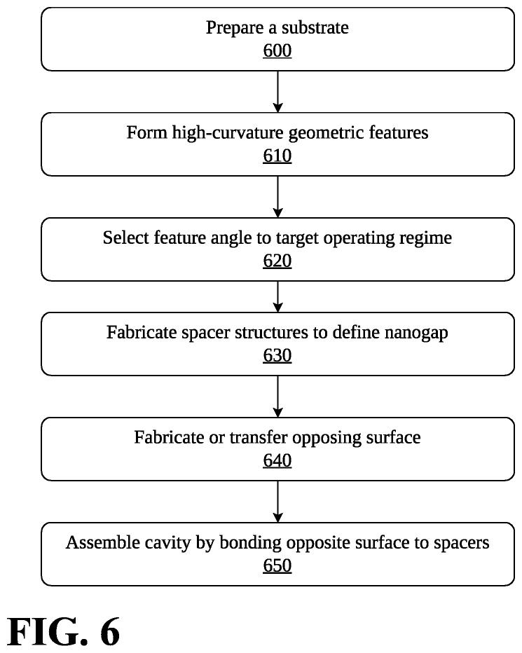

FIG. 6 is a flow diagram illustrating an exemplary method for fabricating a Passive Galvin Cell device. In a first step 600, a substrate is prepared. The substrate provides the structural foundation upon which the device is built and must be suitable for supporting nanoscale geometric features with controlled dimensions. Preparation may include cleaning to remove organic contaminants, oxide layers, and particulate matter using standard semiconductor cleaning procedures. The substrate surface may also be planarized using polishing or chemical-mechanical planarization to achieve the flatness required for maintaining uniform nanoscale gaps. Suitable substrate materials include silicon, silicon carbide, sapphire, metallic substrates, or multilayer composite structures, selected based on compatibility with subsequent fabrication steps, mechanical stability, and the intended operating environment.

In a step 610, high-curvature geometric features are formed on the prepared substrate. These features are the structures that create confined electromagnetic mode trajectories within the eventual cavity region and are responsible for producing geometry-dependent forces and thermal redistribution effects. Formation techniques include photolithographic patterning followed by etching, electron-beam lithography, focused-ion-beam milling, anisotropic wet etching of crystalline substrates, reactive ion etching, nanoimprint lithography, and bottom-up synthesis techniques such as vapor-liquid-solid nanowire growth or template-assisted deposition. The specific technique is selected based on the desired feature geometry, dimensional tolerances, and production volume requirements. Features may be formed as individual structures or as arrays comprising many features distributed across the substrate.

In a step 620, a feature angle is selected to target a desired operating regime. The feature angle is the angle between the edge of each high-curvature geometric feature and a plane parallel to the surface of the structured substrate, and is the primary parameter governing device behavior. The feature angle is set during formation of the geometric features by controlling the etch profile, mask geometry, growth conditions, or deposition angle. Smaller feature angles produce cavity geometries that resemble parallel-plate configurations with relatively weak geometry-dependent effects. Larger feature angles produce re-entrant cavities with stronger effects. Selection of the feature angle determines whether the device operates in a far-subcritical, subcritical, near-critical, supercritical, or far-supercritical regime, with the transitions between regimes depending on the combination of feature angle and nanogap spacing. In exemplary embodiments, feature angles may range from approximately 20 degrees for far-subcritical operation to approximately 85 degrees for far-supercritical operation.

In a step 630, spacer structures are fabricated to define the nanogap. The spacer structures determine the separation distance between the geometric features and the eventual opposing surface, and therefore directly control one of the two primary parameters governing device behavior. Spacers may be formed as pillars, walls, ridges, or other support structures positioned around or among the geometric features. Spacer height may be controlled with nanometer-scale precision using thin-film deposition techniques such as atomic layer deposition. Alternatively, a sacrificial layer of controlled thickness may be deposited over the geometric features, with the sacrificial material later removed to create a free-standing gap. In exemplary embodiments, the nanogap defined by the spacer structures may range from approximately 1 nm to approximately 5000 nm, with many embodiments targeting a range of approximately 1 nm to 200 nm.

In a step 640, an opposing surface is fabricated or transferred. The opposing surface forms the second boundary of the cavity region and may be a rigid plate, a thin membrane, a suspended film, or a multilayer composite structure. Fabrication techniques include chemical vapor deposition, plasma-enhanced chemical vapor deposition, atomic layer deposition, sputter deposition, and evaporation of thin metallic films. In embodiments using two-dimensional materials such as graphene, the material may be grown on a separate substrate and transferred onto the device using established transfer techniques. The opposing surface material is selected based on the intended application, with thermally conductive materials preferred for thermal management applications and mechanically robust materials preferred for applications requiring structural stability.

In a step 650, the cavity is assembled by bonding the opposing surface to the spacer structures. This step creates the enclosed nanogap cavity region between the high-curvature geometric features and the opposing surface. Bonding techniques include direct bonding, anodic bonding, adhesive bonding, or van der Waals bonding in the case of atomically thin materials. In embodiments where a sacrificial layer was deposited in step 630, the sacrificial material is removed after bonding to release the free-standing gap. Care may be taken during this release step to prevent collapse of the opposing surface onto the geometric features due to capillary forces, using techniques such as critical point drying or supercritical fluid drying. Upon completion of this step, all geometric parameters of the device are fixed and the device is ready for deployment without requiring any further active input.

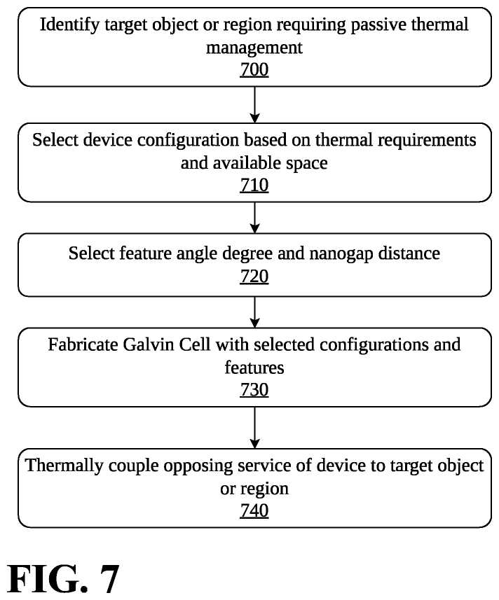

FIG. 7 is a flow diagram illustrating an exemplary method for deploying a Passive Galvin Cell device for passive thermal management. In a first step 700, a target object or region requiring passive thermal management is identified. The target may be any object, component, enclosure, or region that generates or contains thermal energy and for which passive cooling or thermal stabilization is desired. Examples include microelectronic devices, sensor assemblies, optical components, microelectromechanical systems, scientific instruments, sealed enclosures, vacuum chambers, and cryogenic environments. The thermal characteristics of the target are assessed, including the magnitude and spatial distribution of the thermal load, the acceptable temperature range, and any constraints on the thermal management approach such as the absence of available electrical power, the inability to use convective cooling, or restrictions on mechanical vibration from active cooling equipment.

In a step 710, a device configuration is selected based on the thermal requirements and available space. The configuration determines the overall architecture of the device, including whether a single cavity, a uniform feature array, a graded feature array, or a multilayer stacked arrangement is most appropriate for the application. A single cavity or small array may be sufficient for managing a localized thermal load on a compact component. A large-area uniform array may be selected when the thermal load is distributed across a broad surface and uniform cooling is desired. A graded array incorporating features at multiple operating regimes may be selected when the thermal load is spatially non-uniform, allowing the device designer to match stronger thermal redistribution effects to regions of higher heat generation. A multilayer stacked configuration may be selected when the available footprint is limited but the thermal load requires more redistribution capability than a single layer can provide. The available physical space, mechanical constraints, and integration requirements of the target environment also inform the configuration selection.

In a step 720, a feature angle and nanogap distance are selected. These two parameters are the primary geometric variables that determine the operating regime and performance of the device. The feature angle and nanogap distance are selected in combination, as the transition between operating regimes depends on both parameters rather than on either parameter alone. For applications requiring maximum thermal redistribution, a large feature angle in the far-supercritical range combined with a small nanogap may be selected. For applications where moderate geometry-dependent forces are sufficient and fabrication simplicity is preferred, a smaller feature angle combined with a larger nanogap may be appropriate. The selection may also account for the fabrication techniques available, as certain combinations of feature angle and nanogap may be more readily achievable with specific etching, deposition, or growth processes.

In a step 730, a Passive Galvin Cell is fabricated with the selected configurations and features. Fabrication follows the process described in connection with FIG. 6, including substrate preparation, formation of high-curvature geometric features at the selected feature angle, fabrication of spacer structures to define the selected nanogap distance, fabrication or transfer of an opposing surface, and assembly of the cavity by bonding the opposing surface to the spacer structures. The device configuration selected in step 710 determines whether the fabrication produces a single cavity, an array of uniform features, a graded array with multiple feature angles, or a multilayer stack. All geometric parameters are fixed during this fabrication step, and no further adjustment of the device geometry is required or possible after assembly is complete.

In a step 740, the opposing surface of the device is thermally coupled to the target object or region. This step establishes the thermal pathway through which energy from the target enters the cavity region of the device and undergoes geometry-mediated thermal redistribution. Thermal coupling may be achieved by placing the opposing surface in direct physical contact with the target object, by interposing a thermally conductive interface material such as a thermal grease, thermal paste, thermally conductive adhesive, indium foil, or graphite pad between the opposing surface and the target, or by mounting the device within an enclosed cavity or chamber so that thermal energy from the enclosed space reaches the opposing surface through radiation, gas conduction, or molecular heat transfer. The coupling method is selected based on the thermal conductivity requirements, the mechanical constraints of the installation, and the operating environment. Upon completion of this step, the device operates passively and continuously without requiring electrical power, mechanical actuation, or active control signals. The geometry-dependent thermal redistribution effects arise as an inherent consequence of the static cavity geometry and persist for the operational lifetime of the device.

### EXEMPLARY COMPUTING ENVIRONMENT

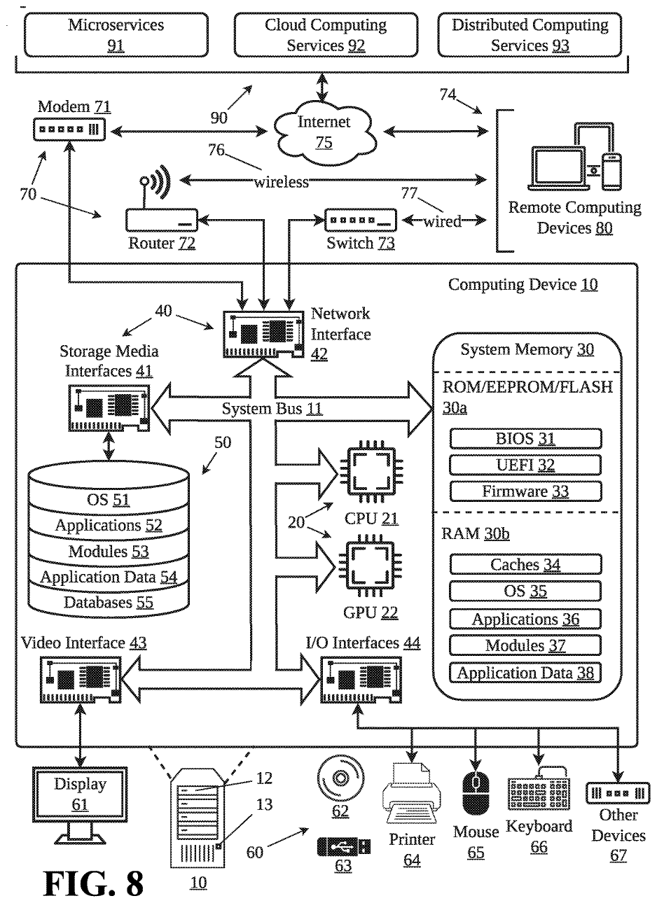

FIG. 8 illustrates an exemplary computing environment on which an embodiment described herein may be implemented, in full or in part. This exemplary computing environment describes computer-related components and processes supporting enabling disclosure of computer-implemented embodiments. Inclusion in this exemplary computing environment of well-known processes and computer components, if any, is not a suggestion or admission that any embodiment is no more than an aggregation of such processes or components. Rather, implementation of an embodiment using processes and components described in this exemplary computing environment will involve programming or configuration of such processes and components resulting in a machine specially programmed or configured for such implementation. The exemplary computing environment described herein is only one example of such an environment and other configurations of the components and processes are possible, including other relationships between and among components, and/or absence of some processes or components described. Further, the exemplary computing environment described herein is not intended to suggest any limitation as to the scope of use or functionality of any embodiment implemented, in whole or in part, on components or processes described herein.

The exemplary computing environment described herein comprises a computing device 10 (further comprising a system bus 11, one or more processors 20, a system memory 30, one or more interfaces 40, one or more non-volatile data storage devices 50), external peripherals and accessories 60, external communication devices 70, remote computing devices 80, and cloud-based services 90.

System bus 11 couples the various system components, coordinating operation of and data transmission between those various system components. System bus 11 represents one or more of any type or combination of types of wired or wireless bus structures including, but not limited to, memory busses or memory controllers, point-to-point connections, switching fabrics, peripheral busses, accelerated graphics ports, and local busses using any of a variety of bus architectures. By way of example, such architectures include, but are not limited to, Industry Standard Architecture (ISA) busses, Micro Channel Architecture (MCA) busses, Enhanced ISA (EISA) busses, Video Electronics Standards Association (VESA) local busses, a Peripheral Component Interconnects (PCI) busses also known as a Mezzanine busses, or any selection of, or combination of, such busses. Depending on the specific physical implementation, one or more of the processors 20, system memory 30 and other components of the computing device 10 can be physically co-located or integrated into a single physical component, such as on a single chip. In such a case, some or all of system bus 11 can be electrical pathways within a single chip structure.

Computing device may further comprise externally-accessible data input and storage devices 12 such as compact disc read-only memory (CD-ROM) drives, digital versatile discs (DVD), or other optical disc storage for reading and/or writing optical discs 62; magnetic cassettes, magnetic tape, magnetic disk storage, or other magnetic storage devices; or any other medium which can be used to store the desired content and which can be accessed by the computing device 10. Computing device may further comprise externally-accessible data ports or connections 13 such as serial ports, parallel ports, universal serial bus (USB) ports, and infrared ports and/or transmitter/receivers. Computing device may further comprise hardware for wireless communication with external devices such as IEEE 1394 (“Firewire”) interfaces, IEEE 802.11 wireless interfaces, BLUETOOTH® wireless interfaces, and so forth. Such ports and interfaces may be used to connect any number of external peripherals and accessories 60 such as visual displays, monitors, and touch-sensitive screens 61, USB solid state memory data storage drives (commonly known as “flash drives” or “thumb drives”) 63, printers 64, pointers and manipulators such as mice 65, keyboards 66, and other devices 67 such as joysticks and gaming pads, touchpads, additional displays and monitors, and external hard drives (whether solid state or disc-based), microphones, speakers, cameras, and optical scanners.

Processors 20 are logic circuitry capable of receiving programming instructions and processing (or executing) those instructions to perform computer operations such as retrieving data, storing data, and performing mathematical calculations. Processors 20 are not limited by the materials from which they are formed or the processing mechanisms employed therein, but are typically comprised of semiconductor materials into which many transistors are formed together into logic gates on a chip (i.e., an integrated circuit or IC). The term processor includes any device capable of receiving and processing instructions including, but not limited to, processors operating on the basis of quantum computing, optical computing, mechanical computing (e.g., using nanotechnology entities to transfer data), and so forth. Depending on configuration, computing device 10 may comprise more than one processor. For example, computing device 10 may comprise one or more central processing units (CPUs) 21, each of which itself has multiple processors or multiple processing cores, each capable of independently or semi-independently processing programming instructions based on technologies like complex instruction set computer (CISC) or reduced instruction set computer (RISC). Further, computing device 10 may comprise one or more specialized processors such as a graphics processing unit (GPU) 22 configured to accelerate processing of computer graphics and images via a large array of specialized processing cores arranged in parallel. Further computing device 10 may be comprised of one or more specialized processes such as Intelligent Processing Units, field-programmable gate arrays or application-specific integrated circuits for specific tasks or types of tasks. The term processor may further include: neural processing units (NPUs) or neural computing units optimized for machine learning and artificial intelligence workloads using specialized architectures and data paths; tensor processing units (TPUs) designed to efficiently perform matrix multiplication and convolution operations used heavily in neural networks and deep learning applications; application-specific integrated circuits (ASICs) implementing custom logic for domain-specific tasks; application-specific instruction set processors (ASIPs) with instruction sets tailored for particular applications; field-programmable gate arrays (FPGAs) providing reconfigurable logic fabric that can be customized for specific processing tasks; processors operating on emerging computing paradigms such as quantum computing, optical computing, mechanical computing (e.g., using nanotechnology entities to transfer data), and so forth. Depending on configuration, computing device 10 may comprise one or more of any of the above types of processors in order to efficiently handle a variety of general purpose and specialized computing tasks. The specific processor configuration may be selected based on performance, power, cost, or other design constraints relevant to the intended application of computing device 10.

System memory 30 is processor-accessible data storage in the form of volatile and/or nonvolatile memory. System memory 30 may be either or both of two types: non-volatile memory and volatile memory. Non-volatile memory 30a is not erased when power to the memory is removed, and includes memory types such as read only memory (ROM), electronically-erasable programmable memory (EEPROM), and rewritable solid state memory (commonly known as “flash memory”). Non-volatile memory 30a is typically used for long-term storage of a basic input/output system (BIOS) 31, containing the basic instructions, typically loaded during computer startup, for transfer of information between components within computing device, or a unified extensible firmware interface (UEFI) 32, which is a modern replacement for BIOS that supports larger hard drives, faster boot times, more security features, and provides native support for graphics and mouse cursors. Non-volatile memory 30a may also be used to store firmware 33 comprising a complete operating system 35 and applications 36 for operating computer-controlled devices. The firmware approach is often used for purpose-specific computer-controlled devices such as appliances and Internet-of-Things (IoT) devices where processing power and data storage space is limited. Volatile memory 30b is erased when power to the memory is removed and is typically used for short-term storage of data for processing. Volatile memory 30b includes memory types such as random-access memory (RAM), and is normally the primary operating memory into which the operating system 35, applications 36, program modules 37, and application data 38 are loaded for execution by processors 20. Volatile memory 30b is generally faster than non-volatile memory 30a due to its electrical characteristics and is directly accessible to processors 20 for processing of instructions and data storage and retrieval. Volatile memory 30b may comprise one or more smaller cache memories 34 which operate at a higher clock speed and are typically placed on the same IC as the processors to improve performance.

There are several types of computer memory, each with its own characteristics and use cases. System memory 30 may be configured in one or more of the several types described herein, including high bandwidth memory (HBM) and advanced packaging technologies like chip-on-wafer-on-substrate (CoWoS). Static random access memory (SRAM) provides fast, low-latency memory used for cache memory in processors, but is more expensive and consumes more power compared to dynamic random access memory (DRAM). SRAM retains data as long as power is supplied. DRAM is the main memory in most computer systems and is slower than SRAM but cheaper and more dense. DRAM requires periodic refresh to retain data. NAND flash is a type of non-volatile memory used for storage in solid state drives (SSDs) and mobile devices and provides high density and lower cost per bit compared to DRAM with the trade-off of slower write speeds and limited write endurance. HBM is an emerging memory technology that provides high bandwidth and low power consumption which stacks multiple DRAM dies vertically, connected by through-silicon vias (TSVs). HBM offers much higher bandwidth (up to 1 TB/s) compared to traditional DRAM and may be used in high-performance graphics cards, AI accelerators, and edge computing devices. Advanced packaging and CoWoS are technologies that enable the integration of multiple chips or dies into a single package. CoWoS is a 2.5D packaging technology that interconnects multiple dies side-by-side on a silicon interposer and allows for higher bandwidth, lower latency, and reduced power consumption compared to traditional PCB-based packaging. This technology enables the integration of heterogeneous dies (e.g., CPU, GPU, HBM) in a single package and may be used in high-performance computing, AI accelerators, and edge computing devices.

Interfaces 40 may include, but are not limited to, storage media interfaces 41, network interfaces 42, display interfaces 43, and input/output interfaces 44. Storage media interface 41 provides the necessary hardware interface for loading data from non-volatile data storage devices 50 into system memory 30 and storage data from system memory 30 to non-volatile data storage device 50. Network interface 42 provides the necessary hardware interface for computing device 10 to communicate with remote computing devices 80 and cloud-based services 90 via one or more external communication devices 70. Display interface 43 allows for connection of displays 61, monitors, touchscreens, and other visual input/output devices. Display interface 43 may include a graphics card for processing graphics-intensive calculations and for handling demanding display requirements. Typically, a graphics card includes a graphics processing unit (GPU) and video RAM (VRAM) to accelerate display of graphics. In some high-performance computing systems, multiple GPUs may be connected using NVLink bridges, which provide high-bandwidth, low-latency interconnects between GPUs. NVLink bridges enable faster data transfer between GPUs, allowing for more efficient parallel processing and improved performance in applications such as machine learning, scientific simulations, and graphics rendering. One or more input/output (I/O) interfaces 44 provide the necessary support for communications between computing device 10 and any external peripherals and accessories 60. For wireless communications, the necessary radio-frequency hardware and firmware may be connected to I/O interface 44 or may be integrated into I/O interface 44. Network interface 42 may support various communication standards and protocols, such as Ethernet and Small Form-Factor Pluggable (SFP). Ethernet is a widely used wired networking technology that enables local area network (LAN) communication. Ethernet interfaces typically use RJ45 connectors and support data rates ranging from 10 Mbps to 100 Gbps, with common speeds being 100 Mbps, 1 Gbps, 10 Gbps, 25 Gbps, 40 Gbps, and 100 Gbps. Ethernet is known for its reliability, low latency, and cost-effectiveness, making it a popular choice for home, office, and data center networks. SFP is a compact, hot-pluggable transceiver used for both telecommunication and data communications applications. SFP interfaces provide a modular and flexible solution for connecting network devices, such as switches and routers, to fiber optic or copper networking cables. SFP transceivers support various data rates, ranging from 100 Mbps to 100 Gbps, and can be easily replaced or upgraded without the need to replace the entire network interface card. This modularity allows for network scalability and adaptability to different network requirements and fiber types, such as single-mode or multi-mode fiber.

Non-volatile data storage devices 50 are typically used for long-term storage of data. Data on non-volatile data storage devices 50 is not erased when power to the non-volatile data storage devices 50 is removed. Non-volatile data storage devices 50 may be implemented using any technology for non-volatile storage of content including, but not limited to, CD-ROM drives, digital versatile discs (DVD), or other optical disc storage; magnetic cassettes, magnetic tape, magnetic disc storage, or other magnetic storage devices; solid state memory technologies such as EEPROM or flash memory; or other memory technology or any other medium which can be used to store data without requiring power to retain the data after it is written. Non-volatile data storage devices 50 may be non-removable from computing device 10 as in the case of internal hard drives, removable from computing device 10 as in the case of external USB hard drives, or a combination thereof, but computing device will typically comprise one or more internal, non-removable hard drives using either magnetic disc or solid state memory technology. Non-volatile data storage devices 50 may be implemented using various technologies, including hard disk drives (HDDs) and solid-state drives (SSDs). HDDs use spinning magnetic platters and read/write heads to store and retrieve data, while SSDs use NAND flash memory. SSDs offer faster read/write speeds, lower latency, and better durability due to the lack of moving parts, while HDDs typically provide higher storage capacities and lower cost per gigabyte. NAND flash memory comes in different types, such as Single-Level Cell (SLC), Multi-Level Cell (MLC), Triple-Level Cell (TLC), and Quad-Level Cell (QLC), each with trade-offs between performance, endurance, and cost. Storage devices connect to the computing device 10 through various interfaces, such as SATA, NVMe, and PCIe. SATA is the traditional interface for HDDs and SATA SSDs, while NVMe (Non-Volatile Memory Express) is a newer, high-performance protocol designed for SSDs connected via PCIe. PCIe SSDs offer the highest performance due to the direct connection to the PCIe bus, bypassing the limitations of the SATA interface. Other storage form factors include M.2 SSDs, which are compact storage devices that connect directly to the motherboard using the M.2 slot, supporting both SATA and NVMe interfaces. Additionally, technologies like Intel Optane memory combine 3D XPoint technology with NAND flash to provide high-performance storage and caching solutions. Non-volatile data storage devices 50 may be non-removable from computing device 10, as in the case of internal hard drives, removable from computing device 10, as in the case of external USB hard drives, or a combination thereof. However, computing devices will typically comprise one or more internal, non-removable hard drives using either magnetic disc or solid-state memory technology. Non-volatile data storage devices 50 may store any type of data including, but not limited to, an operating system 51 for providing low-level and mid-level functionality of computing device 10, applications 52 for providing high-level functionality of computing device 10, program modules 53 such as containerized programs or applications, or other modular content or modular programming, application data 54, and databases 55 such as relational databases, non-relational databases, object oriented databases, NoSQL databases, vector databases, knowledge graph databases, key-value databases, document oriented data stores, and graph databases.

Applications (also known as computer software or software applications) are sets of programming instructions designed to perform specific tasks or provide specific functionality on a computer or other computing devices. Applications are typically written in high-level programming languages such as C, C++, Scala, Erlang, GoLang, Java, Scala, Rust, and Python, which are then either interpreted at runtime or compiled into low-level, binary, processor-executable instructions operable on processors 20. Applications may be containerized so that they can be run on any computer hardware running any known operating system. Containerization of computer software is a method of packaging and deploying applications along with their operating system dependencies into self-contained, isolated units known as containers. Containers provide a lightweight and consistent runtime environment that allows applications to run reliably across different computing environments, such as development, testing, and production systems facilitated by specifications such as containerd.

The memories and non-volatile data storage devices described herein do not include communication media. Communication media are means of transmission of information such as modulated electromagnetic waves or modulated data signals configured to transmit, not store, information. By way of example, and not limitation, communication media includes wired communications such as sound signals transmitted to a speaker via a speaker wire, and wireless communications such as acoustic waves, radio frequency (RF) transmissions, infrared emissions, and other wireless media.

External communication devices 70 are devices that facilitate communications between computing device and either remote computing devices 80, or cloud-based services 90, or both. External communication devices 70 include, but are not limited to, data modems 71 which facilitate data transmission between computing device and the Internet 75 via a common carrier such as a telephone company or internet service provider (ISP), routers 72 which facilitate data transmission between computing device and other devices, and switches 73 which provide direct data communications between devices on a network or optical transmitters (e.g., lasers). Here, modem 71 is shown connecting computing device 10 to both remote computing devices 80 and cloud-based services 90 via the Internet 75. While modem 71, router 72, and switch 73 are shown here as being connected to network interface 42, many different network configurations using external communication devices 70 are possible. Using external communication devices 70, networks may be configured as local area networks (LANs) for a single location, building, or campus, wide area networks (WANs) comprising data networks that extend over a larger geographical area, and virtual private networks (VPNs) which can be of any size but connect computers via encrypted communications over public networks such as the Internet 75. As just one exemplary network configuration, network interface 42 may be connected to switch 73 which is connected to router 72 which is connected to modem 71 which provides access for computing device 10 to the Internet 75. Further, any combination of wired 77 or wireless 76 communications between and among computing device 10, external communication devices 70, remote computing devices 80, and cloud-based services 90 may be used. Remote computing devices 80, for example, may communicate with computing device through a variety of communication channels 74 such as through switch 73 via a wired 77 connection, through router 72 via a wireless connection 76, or through modem 71 via the Internet 75. Furthermore, while not shown here, other hardware that is specifically designed for servers or networking functions may be employed. For example, secure socket layer (SSL) acceleration cards can be used to offload SSL encryption computations, and transmission control protocol/internet protocol (TCP/IP) offload hardware and/or packet classifiers on network interfaces 42 may be installed and used at server devices or intermediate networking equipment (e.g., for deep packet inspection).

In a networked environment, certain components of computing device 10 may be fully or partially implemented on remote computing devices 80 or cloud-based services 90. Data stored in non-volatile data storage device 50 may be received from, shared with, duplicated on, or offloaded to a non-volatile data storage device on one or more remote computing devices 80 or in a cloud computing service 92. Processing by processors 20 may be received from, shared with, duplicated on, or offloaded to processors of one or more remote computing devices 80 or in a distributed computing service 93. By way of example, data may reside on a cloud computing service 92, but may be usable or otherwise accessible for use by computing device 10. Also, certain processing subtasks may be sent to a microservice 91 for processing with the result being transmitted to computing device 10 for incorporation into a larger processing task. Also, while components and processes of the exemplary computing environment are illustrated herein as discrete units (e.g., OS 51 being stored on non-volatile data storage device 51 and loaded into system memory 35 for use) such processes and components may reside or be processed at various times in different components of computing device 10, remote computing devices 80, and/or cloud-based services 90. Also, certain processing subtasks may be sent to a microservice 91 for processing with the result being transmitted to computing device 10 for incorporation into a larger processing task. Infrastructure as Code (IaaC) tools like Terraform can be used to manage and provision computing resources across multiple cloud providers or hyperscalers. This allows for workload balancing based on factors such as cost, performance, and availability. For example, Terraform can be used to automatically provision and scale resources on AWS spot instances during periods of high demand, such as for surge rendering tasks, to take advantage of lower costs while maintaining the required performance levels. In the context of rendering, tools like Blender can be used for object rendering of specific elements, such as a car, bike, or house. These elements can be approximated and roughed in using techniques like bounding box approximation or low-poly modeling to reduce the computational resources required for initial rendering passes. The rendered elements can then be integrated into the larger scene or environment as needed, with the option to replace the approximated elements with higher-fidelity models as the rendering process progresses.

In an implementation, the disclosed systems and methods may utilize, at least in part, containerization techniques to execute one or more processes and/or steps disclosed herein. Containerization is a lightweight and efficient virtualization technique that allows you to package and run applications and their dependencies in isolated environments called containers. One of the most popular containerization platforms is containerd, which is widely used in software development and deployment. Containerization, particularly with open-source technologies like containerd and container orchestration systems like Kubernetes, is a common approach for deploying and managing applications. Containers are created from images, which are lightweight, standalone, and executable packages that include application code, libraries, dependencies, and runtime. Images are often built from a containerfile or similar, which contains instructions for assembling the image. Containerfiles are configuration files that specify how to build a container image. Systems like Kubernetes natively support containerd as a container runtime. They include commands for installing dependencies, copying files, setting environment variables, and defining runtime configurations. Container images can be stored in repositories, which can be public or private. Organizations often set up private registries for security and version control using tools such as Harbor, JFrog Artifactory and Bintray, GitLab Container Registry, or other container registries. Containers can communicate with each other and the external world through networking. Containerd provides a default network namespace, but can be used with custom network plugins. Containers within the same network can communicate using container names or IP addresses.

Remote computing devices 80 are any computing devices not part of computing device 10. Remote computing devices 80 include, but are not limited to, personal computers, server computers, thin clients, thick clients, personal digital assistants (PDAs), mobile telephones, watches, tablet computers, laptop computers, multiprocessor systems, microprocessor based systems, set-top boxes, programmable consumer electronics, video game machines, game consoles, portable or handheld gaming units, network terminals, desktop personal computers (PCs), minicomputers, mainframe computers, network nodes, virtual reality or augmented reality devices and wearables, and distributed or multi-processing computing environments. While remote computing devices 80 are shown for clarity as being separate from cloud-based services 90, cloud-based services 90 are implemented on collections of networked remote computing devices 80.

Cloud-based services 90 are Internet-accessible services implemented on collections of networked remote computing devices 80. Cloud-based services are typically accessed via application programming interfaces (APIs) which are software interfaces which provide access to computing services within the cloud-based service via API calls, which are pre-defined protocols for requesting a computing service and receiving the results of that computing service. While cloud-based services may comprise any type of computer processing or storage, three common categories of cloud-based services 90 are serverless logic apps, microservices 91, cloud computing services 92, and distributed computing services 93.

Microservices 91 are collections of small, loosely coupled, and independently deployable computing services. Each microservice represents a specific computing functionality and runs as a separate process or container. Microservices promote the decomposition of complex applications into smaller, manageable services that can be developed, deployed, and scaled independently. These services communicate with each other through well-defined application programming interfaces (APIs), typically using lightweight protocols like HTTP, protobuffers, gRPC or message queues such as Kafka. Microservices 91 can be combined to perform more complex or distributed processing tasks. In an embodiment, Kubernetes clusters with containerized resources are used for operational packaging of system.

Cloud computing services 92 are delivery of computing resources and services over the Internet 75 from a remote location. Cloud computing services 92 provide additional computer hardware and storage on as-needed or subscription basis. Cloud computing services 92 can provide large amounts of scalable data storage, access to sophisticated software and powerful server-based processing, or entire computing infrastructures and platforms. For example, cloud computing services can provide virtualized computing resources such as virtual machines, storage, and networks, platforms for developing, running, and managing applications without the complexity of infrastructure management, and complete software applications over public or private networks or the Internet on a subscription or alternative licensing basis, or consumption or ad-hoc marketplace basis, or combination thereof.

Distributed computing services 93 provide large-scale processing using multiple interconnected computers or nodes to solve computational problems or perform tasks collectively. In distributed computing, the processing and storage capabilities of multiple machines are leveraged to work together as a unified system. Distributed computing services are designed to address problems that cannot be efficiently solved by a single computer or that require large-scale computational power or support for highly dynamic compute, transport or storage resource variance or uncertainty over time requiring scaling up and down of constituent system resources. These services enable parallel processing, fault tolerance, and scalability by distributing tasks across multiple nodes.

Although described above as a physical device, computing device 10 can be a virtual computing device, in which case the functionality of the physical components herein described, such as processors 20, system memory 30, network interfaces 40, NVLink or other GPU-to-GPU high bandwidth communications links and other like components can be provided by computer-executable instructions. Such computer-executable instructions can execute on a single physical computing device, or can be distributed across multiple physical computing devices, including being distributed across multiple physical computing devices in a dynamic manner such that the specific, physical computing devices hosting such computer-executable instructions can dynamically change over time depending upon need and availability. In the situation where computing device 10 is a virtualized device, the underlying physical computing devices hosting such a virtualized computing device can, themselves, comprise physical components analogous to those described above, and operating in a like manner. Furthermore, virtual computing devices can be utilized in multiple layers with one virtual computing device executing within the construct of another virtual computing device. Thus, computing device 10 may be either a physical computing device or a virtualized computing device within which computer-executable instructions can be executed in a manner consistent with their execution by a physical computing device. Similarly, terms referring to physical components of the computing device, as utilized herein, mean either those physical components or virtualizations thereof performing the same or equivalent functions.

The skilled person will be aware of a range of possible modifications of the various aspects described above. Accordingly, the present invention is defined by the claims and their equivalents.

What is claimed is:

1. A passive nanoscale cavity device comprising:
a structured substrate;
one or more high-curvature geometric features extending from the structured substrate, each high-curvature geometric feature having a feature angle defined between an edge of the high-curvature geometric feature and a plane parallel to a surface of the structured substrate;
an opposing substrate positioned opposite the one or more high-curvature geometric features;
a nanogap between a tip of at least one of the one or more high-curvature geometric features and the opposing substrate;
one or more substrate supports between the structured substrate and the opposing substrate configured to maintain the nanogap; and
a cavity region defined between cell walls of the one or more high-curvature geometric features and the opposing substrate, the cavity region configured to support electromagnetic mode trajectories that produce geometry-dependent forces and thermal energy redistribution effects,
wherein the device operates passively without externally applied electrical power, electromagnetic drive fields, or mechanical actuation.

2. The device of claim 1, wherein the nanogap has a distance in the range of 1 nanometer to 5000 nanometers.

3. The device of claim 1, wherein the nanogap has a distance in the range of 1 nanometer to 200 nanometers.

4. The device of claim 1, wherein the feature angle of at least one of the one or more high-curvature geometric features is in a far-supercritical range of approximately 60 degrees to approximately 85 degrees such that geometry-dependent forces within the cavity region have reached a plateau value and the thermal energy redistribution effects are active.

5. The device of claim 1, wherein the feature angle of at least one of the one or more high-curvature geometric features is in a supercritical range of approximately 45 degrees to approximately 50 degrees.

6. The device of claim 1, wherein the feature angle of at least one of the one or more high-curvature geometric features is in a near-critical range of approximately 45 degrees such that the device exhibits sensitivity to variations in geometric parameters.

7. The device of claim 1, wherein the one or more high-curvature geometric features comprise structures selected from the group consisting of: frustums, cones, pointed spires, rounded spires, triangular features, cylindrical features, nanowires, graphene edges, ridges, and fractal or hierarchical structures.

8. The device of claim 1, wherein the opposing substrate comprises a thin membrane having a thickness in the range of several nanometers to several hundred nanometers.

9. The device of claim 1, wherein high-curvature geometric features are present on both the structured substrate and the opposing substrate, producing bilateral curvature concentration within the cavity region.

10. The device of claim 1, further comprising a plurality of the one or more high-curvature geometric features arranged in a feature array on the structured substrate.

11. The device of claim 10, wherein the feature array comprises a pattern selected from the group consisting of: periodic arrays, quasi-periodic arrays, graded arrays, and nanowire forest configurations.

12. The device of claim 10, wherein the plurality of the one or more high-curvature geometric features within the feature array comprise different feature angles to produce spatially varying operating regimes across the structured substrate.

13. The device of claim 12, wherein the feature array comprises a far-supercritical feature having a first feature angle, a supercritical feature having a second feature angle smaller than the first feature angle, and a near-critical feature having a third feature angle smaller than the second feature angle.

14. The device of claim 1, wherein the opposing substrate is thermally coupled to a heat source through a thermal interface, and wherein thermal energy from the heat source passes through the thermal interface into the opposing substrate and undergoes geometry-mediated thermal redistribution within the cavity region.

15. The device of claim 14, wherein the heat source comprises an object selected from the group consisting of: microelectronic devices, sensor assemblies, optical components, microelectromechanical systems, scientific instruments, sealed enclosures, vacuum chambers, and cryogenic environments.
